(19) United States
(12) Patent Application Publication
(10) Pub. No.: US 2025/0221315 A1
(43) Pub. Date: Jul. 3, 2025

(54) VIBRATION APPARATUS, METHOD OF MANUFACTURING THE SAME, AND VIBRATION DRIVING VIBRATION DRIVING DEVICE INCLUDING THE VIBRATION APPARATUS

(71) Applicant: LG Display Co., Ltd., Seoul (KR)

(72) Inventors: Uihyeon JEONG, Paju-si (KR); JounHo LEE, Paju-si (KR); Sooyoun KIM, Paju-si (KR); YongWoo LEE, Paju-si (KR); HwaYoul LEE, Paju-si (KR); Daesu KIM, Paju-si (KR)

(21) Appl. No.: 18/933,515

(22) Filed: Oct. 31, 2024

(30) Foreign Application Priority Data
Dec. 28, 2023 (KR) 10-2023-0195758

(51) Int. Cl. H10N 30/87; H10N 30/063; H10N 30/50; H10N 30/80; H10N 30/88

(52) U.S. Cl. CPC H10N 30/872; H10N 30/063; H10N 30/50; H10N 30/802; H10N 30/875; H10N 30/88

(57) ABSTRACT

A vibration apparatus can comprise a vibration generating part including a plurality of vibration parts, and a connection layer welded between the plurality of vibration parts. The connection layer can comprise a conductive material.

### CROSS-REFERENCE TO RELATED APPLICATIONS

This application claims the benefit of the Korean Patent Application No. 10-2023-0195758 filed on Dec. 28, 2023, which is hereby incorporated by reference as if fully set forth herein.

### BACKGROUND

### Technical Field

The present disclosure relates to a vibration apparatus, a method of manufacturing the same, and an vibration driving device including the vibration apparatus.

### Description of the Related Art

Recently, the demands for slimmer and thinner electronic devices are increasing. In speakers applied to electronic devices, piezoelectric devices capable of being implemented with a thin thickness are attracting much attention instead of voice coils, based on the demands for slimmer and thinner devices.

Speakers or vibration apparatuses, to which a piezoelectric device is applied, may be driven or vibrated by a driving power or a driving signal supplied through a signal cable.

### BRIEF SUMMARY

The inventors have performed extensive research and experiments for implementing a vibration apparatus where a manufacturing process and a structure of the vibration apparatus are simplified. The inventors have invented a vibration apparatus having a new structure and a method of manufacturing the same, and an vibration driving device including the vibration apparatus, in which a manufacturing process and a structure of the vibration apparatus are simplified, based on the extensive research and experiments.

One or more embodiment of the present disclosure are directed to providing a vibration apparatus, a method of manufacturing the same, and an vibration driving device including the vibration apparatus, in which a structure thereof and a manufacturing process are simplified.

One or more embodiment of the present disclosure are directed to providing a vibration apparatus, a method of manufacturing the same, and an vibration driving device including the vibration apparatus, in which a weight and a thickness may be reduced.

One or more embodiment of the present disclosure are directed to providing a vibration apparatus, a method of manufacturing the same, and an vibration driving device including the vibration apparatus, which may improve a sound pressure level characteristic of a sound.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and embodiment of the present disclosure, as embodied and broadly described herein, in one or more embodiments, a vibration apparatus can comprise a vibration generating part including a plurality of vibration parts, and a connection layer welded between the plurality of vibration parts. The connection layer can comprise a conductive material.

A method of manufacturing a vibration apparatus, the method can comprise a step of configuring a vibration generating part including a plurality of vibration parts, a step of configuring a connection layer welded between the plurality of vibration parts, a step of configuring a signal cable electrically connected to the plurality of vibration parts, a step of respectively configuring first and second cover members at a first surface and a second surface of the vibration generating part. The connection layer can comprise a conductive material.

A vibration driving device can comprise a passive vibration member, a vibration generating apparatus connected to the passive vibration member to vibrate the passive vibration member. The vibration generating apparatus can comprise the vibration apparatus. The vibration apparatus can comprise a vibration generating part including a plurality of vibration parts, and a connection layer welded between the plurality of vibration parts. The connection layer can comprise a conductive material.

According to an embodiment of the present disclosure, a vibration apparatus capable of simplifying a structure and a manufacturing process and a method of manufacturing the same, and an vibration driving device including the vibration apparatus can be provided.

According to an embodiment of the present disclosure, since the thickness of the vibration apparatus may be reduced to reduce weight, it is possible to implement a lightweight vibration apparatus.

According to an embodiment of the present disclosure, process optimization through energy-saving production may be achieved by simplifying the manufacturing process.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a diagram illustrating a vibration apparatus according to an embodiment of the present disclosure;

FIG. 2 is an exploded perspective view illustrating a connection structure between a vibration generating part and a signal cable illustrated in FIG. 1 according to an embodiment of the present disclosure;

FIG. 3 is a cross-sectional view taken along line A-A′ illustrated in FIG. 1 according to an embodiment of the present disclosure;

FIG. 4 is a cross-sectional view taken along line B-B′ illustrated in FIG. 1 according to an embodiment of the present disclosure;

FIG. 5 is a cross-sectional view taken along line C-C′ illustrated in FIG. 1 according to an embodiment of the present disclosure;

FIG. 6 is a cross-sectional view taken along line D-D′ illustrated in FIG. 1 according to an embodiment of the present disclosure;

FIGS. 7A to 7C are diagrams illustrating a method of manufacturing the vibration apparatus illustrated in FIG. 1 according to an embodiment of the present disclosure;

FIG. 8 is a diagram illustrating a method of manufacturing the vibration apparatus illustrated in FIG. 1 according to another embodiment of the present disclosure;

FIG. 9 is a diagram illustrating a vibration apparatus according to another embodiment of the present disclosure;

FIG. 10 is an exploded perspective view illustrating a connection structure between a vibration generating part and a signal cable illustrated in FIG. 9 according to another embodiment of the present disclosure;

FIG. 11 is a cross-sectional view taken along line E-E′ illustrated in FIG. 9 according to an embodiment of the present disclosure;

FIG. 12 is a cross-sectional view taken along line F-F′ illustrated in FIG. 9 according to an embodiment of the present disclosure;

FIG. 13 is a cross-sectional view taken along line G-G′ illustrated in FIG. 9 according to an embodiment of the present disclosure;

FIG. 14 is a cross-sectional view taken along line H-H′ illustrated in FIG. 9 according to an embodiment of the present disclosure;

FIGS. 15A to 15C are diagrams illustrating a method of manufacturing the vibration apparatus illustrated in FIG. 9 according to an embodiment of the present disclosure;

FIG. 16 is a cross-sectional view taken along line E-E′ illustrated in FIG. 9 according to another embodiment of the present disclosure;

FIGS. 17A to 17D are diagrams illustrating a method of manufacturing the vibration apparatus illustrated in FIG. 16 according to another embodiment of the present disclosure;

FIG. 18 is a diagram illustrating a vibration driving device according to an embodiment of the present disclosure; and

FIG. 19 is a cross-sectional view taken along line I-I′ illustrated in FIG. 18 according to an embodiment of the present disclosure.

### DETAILED DESCRIPTION

Reference is now made in detail to embodiments of the present disclosure, examples of which may be illustrated in the accompanying drawings. In the following description, when a detailed description of well-known methods, functions or configurations may unnecessarily obscure embodiments of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more embodiments, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

The shapes, sizes, areas, widths, heights, thicknesses, ratios, angles, numbers, the number of elements, and the like disclosed in the drawings for describing embodiments of the present disclosure are merely examples, and thus, the present disclosure is not limited to the illustrated details. When the term “comprise,” “have,” “include,” “contain,” “constitute,” “made of,” “formed of,” “composed of,” or the like is used, one or more elements (e.g., layers, films, regions, components, sections, members, parts, regions, areas, portions, steps, operations, and/or the like) may be added unless a term such as “only” or the like is used. The terms used in the present disclosure are merely used to describe particular embodiments, and are not intended to limit the scope of the present disclosure. The terms used herein are merely used to describe example embodiments, and are not intended to limit the scope of the present disclosure. The terms of a singular form may include plural forms unless the context clearly indicates otherwise. The word “exemplary” is used to mean serving as an example or illustration. An embodiment may be one or more example embodiments. Embodiments are example embodiments. Any implementation described herein as an “example” or “embodiment” is not necessarily to be construed as preferred or advantageous over other implementations.

In one or more embodiments, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompass all the meanings of the term “may.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements (e.g., layers, films, regions, components, sections, members, parts, regions, areas, portions, steps, operations, and/or the like), these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these terms are not used to define the essence, basis, order, or number of the elements.

For the expression that an element (e.g., layer, film, region, component, section, or the like) is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with the another element, but also indirectly contact, overlap, or the like with another element with one or more intervening elements disposed or interposed between the elements or layers, unless otherwise specified.

The terms such as a “line” or “direction” should not be interpreted only based on a geometrical relationship in which the respective lines or directions are parallel or perpendicular to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item,” may represent (i) a combination of items provided one or more of the first item, the second item, and the third item and (ii) only one of the first item, the second item, and the third item.

The expression of a first element, a second elements “and/or” a third element should be understood to encompass one of the first, second, and third elements, as well as any or all combinations of the first, second and third elements. By way of example, A, B and/or C encompass only A; only B; only C; any of A, B, and C (e.g., A, B, or C; some combination of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more embodiments, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more embodiments, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more embodiments, the phrases “one or more among” and “one or more of” may be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, or may be operated, linked or driven together in various ways. Embodiments of the present disclosure may be implemented or carried out independently from each other, or may be implemented or carried out together in a co-dependent or related relationship. In one or more embodiments, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field. However, there may be other terms than the terms depending on the development and/or change of technology, convention, preference of technicians, etc. Therefore, the terms used herein should not be understood as limiting technical ideas, but should be understood as examples of the terms for illustrating embodiments.

Further, in a specific case, a term may be arbitrarily selected by the applicant, and in this case, the detailed meaning thereof is described herein. Therefore, the terms used herein should be understood based on not only simply the name of the terms, but also the meaning of the terms and the contents thereof.

“X-axis direction,” “Y-axis direction” and “Z-axis direction” should not be construed by a geometric relation only of a mutual vertical relation and may have broader directionality within the range that elements of the present disclosure may act functionally.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

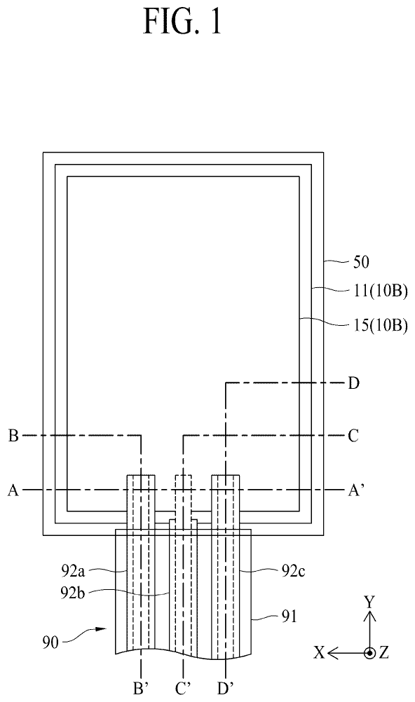

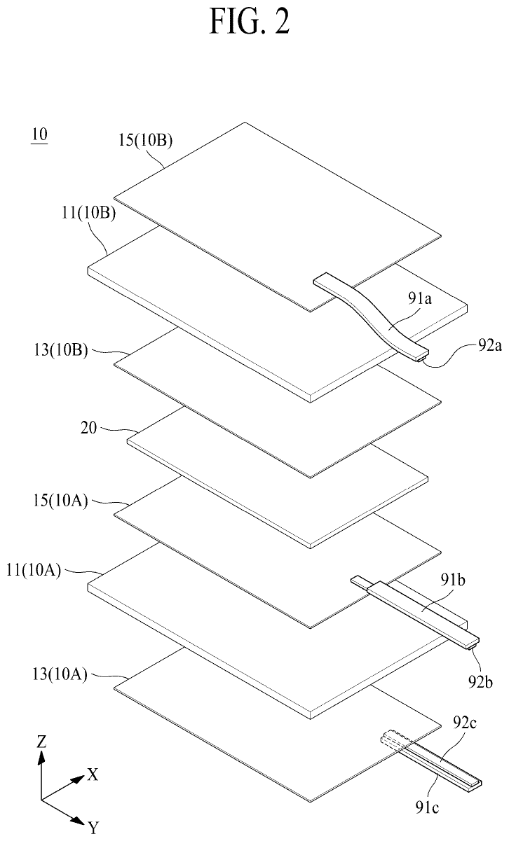

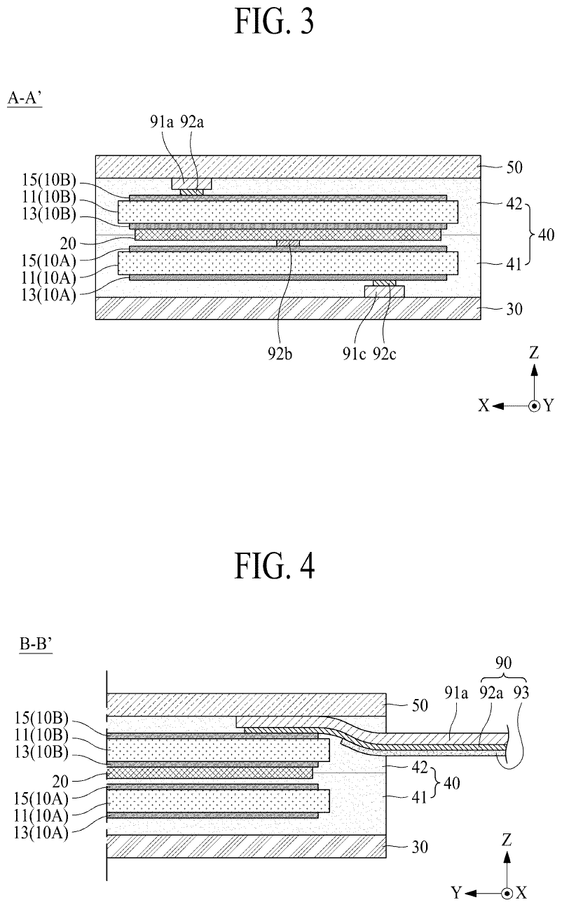

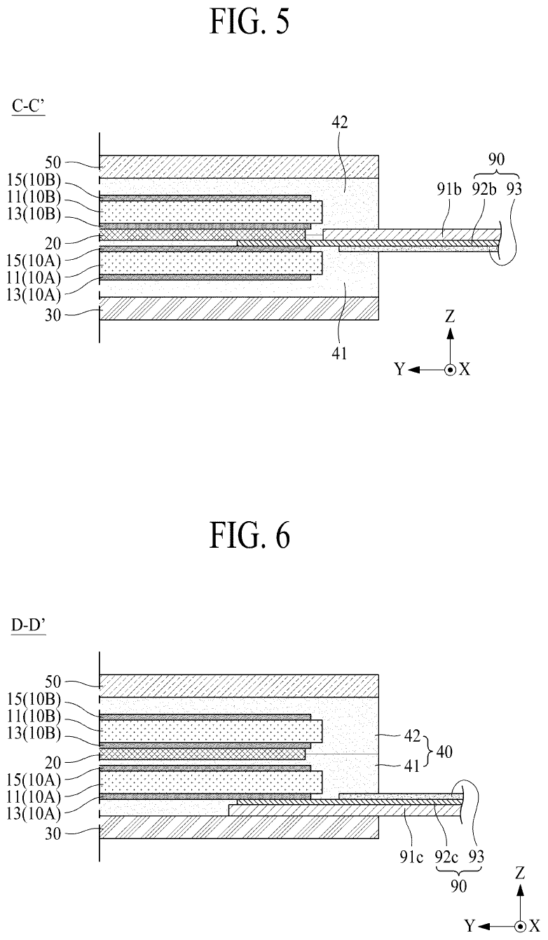

FIG. 1 is a diagram illustrating a vibration apparatus according to an embodiment of the present disclosure. FIG. 2 is an exploded perspective view illustrating a connection structure between a vibration generating part and a signal cable illustrated in FIG. 1 according to an embodiment of the present disclosure. FIG. 3 is a cross-sectional view taken along line A-A′ illustrated in FIG. 1 according to an embodiment of the present disclosure. FIG. 4 is a cross-sectional view taken along line B-B′ illustrated in FIG. 1 according to an embodiment of the present disclosure. FIG. 5 is a cross-sectional view taken along line C-C′ illustrated in FIG. 1 according to an embodiment of the present disclosure. FIG. 6 is a cross-sectional view taken along line D-D′ illustrated in FIG. 1 according to an embodiment of the present disclosure.

Referring to FIGS. 1 to 6, a vibration apparatus according to an embodiment of the present disclosure can include a vibration generating part 10 and a connection layer 20.

The vibration generating part 10 may include a plurality of vibration parts 10A and 10B. For example, the vibration generating part 10 can include the plurality of vibration parts 10A and 10B which overlap each other or are overlaid. For example, the vibration generating part 10 can include the plurality of vibration parts 10A and 10B which are stacked or overlap each other. For example, the vibration generating part 10 can include a first vibration part 10A and a second vibration part 10B stacked on the first vibration part 10A.

According to an embodiment of the present disclosure, each of the first vibration part 10A and the second vibration part 10B can include a piezoelectric material (or an electroactive material), or a piezoelectric device, which has a piezoelectric effect. Thus, the first vibration part 10A and the second vibration part 10B may also be referred to herein as piezoelectric layers 10A, 10B. The piezoelectric layers 10A, 10B may be only a single layer or a layer stack of two or more layers. For example, the piezoelectric material (or the piezoelectric device) can have a characteristic where pressure or twisting is applied to a crystal structure by an external force, a potential difference occurs due to dielectric polarization caused by a relative position change of a positive (+) ion and a negative (−) ion, and a vibration is generated by an electric field based on a voltage applied thereto.

Each of the first vibration part 10A and the second vibration part 10B can include a vibration layer 11, a first electrode layer 13, and a second electrode layer 15.

The vibration layer 11 can include a piezoelectric material (or an electroactive material) having a piezoelectric effect. The vibration layer 11 can include a ceramic-based material for implementing a relatively strong vibration, or can include piezoelectric ceramic having a perovskite-based crystalline structure.

The piezoelectric ceramic can include single crystalline ceramic having a single-crystal structure, or can include a ceramic material or polycrystalline ceramic having a poly-crystal structure. A piezoelectric material including single crystalline ceramic can include one or more of aluminum phosphate (for example, α-AlPO₄), silicon dioxide (for example, α-SiO₂), lithium niobate (LiNbO₃), terbium molydbate (Tb₂(MoO₄)₃), lithium tetraborate (Li₂B₄O₇), or ZnO. The piezoelectric material including single crystalline ceramic can include a lead zirconate titanate (PZT)-based material including lead (Pb), zirconium (Zr), and titanium (Ti) or can include a lead zirconate nickel niobate (PZNN)-based material including lead (Pb), zirconium (Zr), nickel (Ni), and niobium (Nb), but embodiments of the present disclosure are not limited thereto. As another example, the vibration layer 11 can include at least one of CaTiO₃, BaTiO₃, and SrTiO₃ without lead (Pb), but embodiments of the present disclosure are not limited thereto.

According to an embodiment of the present disclosure, the vibration layer 11 of each of the first vibration part 10A and the second vibration part 10B can have a same ceramic crystalline structure, or can have different ceramic crystalline structures. For example, the vibration layer 11 of the first vibration part 10A and the vibration layer 11 of the second vibration part 10B can include single crystalline ceramic or polycrystalline ceramic. For example, one of the vibration layer 11 of the first vibration part 10A and the vibration layer 11 of the second vibration part 10B can include single crystalline ceramic, and the other can include polycrystalline ceramic.

According to an embodiment of the present disclosure, in each of a first vibration part 10A and a second vibration part 10B, a vibration layer 11 can be configured (or disposed) between a first electrode layer 13 and a second electrode layer 15.

In the first vibration part 10A, the first electrode layer 13 can be disposed at a first surface (or a lower surface) of the vibration layer 11. The first electrode layer 13 can have a same size as that of the vibration layer 11 or can have a size which is less than that of the vibration layer 11, but embodiments of the present disclosure are not limited thereto. For example, the first electrode layer 13 can be a single-electrode. For example, the first electrode layer 13 can include a tetragonal shape. For example, an end (or a lateral surface) of the first electrode layer 13 can be spaced apart from an end (or a lateral surface) of the vibration layer 11, and thus, an electrical connection (or short circuit) between the first electrode layer 13 and the second electrode layer 15 can be prevented. For example, the first electrode layer 13 of the first vibration part 10A can be a first electrode layer, a lower electrode layer, or a lowermost electrode layer of the vibration generating part 10, but embodiments of the present disclosure are not limited thereto.

In the first vibration part 10A, the second electrode layer 15 can be disposed at a second surface (or an upper surface), which is different from or opposite to the first surface, of the vibration layer 11. The second electrode layer 15 can have a size which is less than that of the vibration layer 11, but embodiments of the present disclosure are not limited thereto. For example, the second electrode layer 15 of the first vibration part 10A can be the second electrode layer of the vibration generating part 10, but embodiments of the present disclosure are not limited thereto.

In the second vibration part 10B, the first electrode layer 13 can be disposed at a first surface (or a lower surface). The first electrode layer 13 can have a size which is less than that of the vibration layer 11, but embodiments of the present disclosure are not limited thereto. For example, the first electrode layer 13 of the second vibration part 10B can be a third electrode layer of the vibration generating part 10, but embodiments of the present disclosure are not limited thereto.

In the second vibration part 10B, the second electrode layer 15 can be disposed at the second surface (or the upper surface), which is different from or opposite to the first surface, of the vibration layer 11. The second electrode layer 15 can have a size which is less than that of the vibration layer 11, but embodiments of the present disclosure are not limited thereto. For example, the second electrode layer 15 of the second vibration part 10B can be a fourth electrode layer, an upper electrode layer, or an uppermost electrode layer of the vibration generating part 10, but embodiments of the present disclosure are not limited thereto.

According to an embodiment of the present disclosure, the second electrode layer 15 of the first vibration part 10A and the first electrode layer 13 of the second vibration part 10B can be disposed adjacent to each other. According to an embodiment of the present disclosure, because the second electrode layer 15 of the first vibration part 10A and the first electrode layer 13 of the second vibration part 10B are disposed adjacent to each other, a polarization direction (or a poling direction) formed in the vibration layer 11 of the first vibration part 10A and a polarization direction (or a poling direction) formed in the vibration layer 11 of the second vibration part 10B can be configured to be different directions or opposite directions. For example, the polarization direction formed in the vibration layer 11 of the first vibration part 10A can be configured toward the second electrode layer 15 from the first electrode layer 13, and the polarization direction formed in the vibration layer 11 of the second vibration part 10B can be configured toward the first electrode layer 13 from the second electrode layer 15. However, embodiments of the present disclosure are not limited thereto.

In a stack structure of the first and second vibration parts 10A and 10B, to prevent electrical short circuit between electrode layers vertically adjacent to each other, each of the first electrode layer 13 and the second electrode layer 15 can be formed at the other portion, except an edge portion of the vibration layer 11. For example, a distance between a lateral surface of each of the first electrode layer 13 and the second electrode layer 15, and a lateral surface of the vibration layer 11 can be at least 0.5 mm or more, but embodiments of the present disclosure are not limited thereto. For example, the distance between the lateral surface of each of the first electrode layer 13 and the second electrode layer 15, and the lateral surface of the vibration layer 11 can be at least 1 mm or more, but embodiments of the present disclosure are not limited thereto.

According to an embodiment of the present disclosure, one or more of the first electrode layer 13 and the second electrode layer 15 can include material fired at a high temperature. For example, one or more of the first electrode layer 13 and the second electrode layer 15 can include a transparent conductive material, a semitransparent conductive material, or an opaque conductive material, but embodiments of the present disclosure are not limited thereto. For example, the transparent or semitransparent conductive material can include one or more of indium tin oxide (ITO) or indium zinc oxide (IZO), but embodiments of the present disclosure are not limited thereto. The opaque conductive material can include gold (Au), silver (Ag), platinum (Pt), palladium (Pd), molybdenum (Mo), magnesium (Mg), carbon, or silver (Ag) including a grass frit, or an alloy thereof, but embodiments of the present disclosure are not limited thereto. For example, carbon can be a carbon material including carbon black, ketjen black, carbon nanotube, and graphite, but embodiments of the present disclosure are not limited thereto. According to an embodiment of the present disclosure, each of the first electrode layer 13 and the second electrode layer 15 can include silver (Ag) having a low resistivity, to enhance an electrical characteristic and/or a vibration characteristic of the vibration layer 11.

In the first electrode layer 13 and the second electrode layer 15 including glass frit including silver (Ag), a content of glass frit can be about 1 wt % or more to about 12 wt % or less, but embodiments of the present disclosure are not limited thereto. The glass frit can include a material based on PbO or Bi₂O₃, but embodiments of the present disclosure are not limited thereto. For example, an oxide of bismuth (Bi), an oxide of zinc (Zn), an oxide of aluminum (Al), an oxide of boron (B), and/or an oxide of silicone (Si), but embodiments of the present disclosure are not limited thereto.

According to an embodiment of the present disclosure, the plurality of vibration parts 10A and 10B or the first and second vibration parts 10A and 10B can be connected to or contact each other. The plurality of vibration parts 10A and 10B can be connected to each other through the connection layer 20 configured between the plurality of vibration parts 10A and 10B. For example, the plurality of vibration parts 10A and 10B or the first and second vibration parts 10A and 10B can contact each other through the connection layer 20.

According to an embodiment of the present disclosure, the connection layer 20 can be welded between the plurality of vibration parts 10A and 10B. The connection layer 20 can be welded between the second electrode layer 15 of the first vibration part 10A and the first electrode layer 13 of the second vibration part 10B. Based on welding, the connection layer 20 can electrically connect the second electrode layer 15 of the first vibration part 10A to the first electrode layer 13 of the second vibration part 10B.

According to an embodiment of the present disclosure, the connection layer 20 can include a conductive material. For example, the connection layer 20 can include a conductive material having a melting point of 400° C. or less. For example, the conductive material can be a soldering foil or a soldering foil including silver (Ag), but embodiments of the present disclosure are not limited thereto. According to an embodiment of the present disclosure, the connection layer 20 can be an internal connection layer or an electrode connection layer, but embodiments of the present disclosure are not limited thereto.

According to an embodiment of the present disclosure, the vibration layer 11 of the first vibration part 10A and the vibration layer 11 of the second vibration part 10B can be polarized (or poling) in the same direction, or can be polarized (or poling) in opposite (or different) directions. For example, a polarization direction (or a poling direction) formed in the vibration layer 11 of the first vibration part 10A can be a direction which is different from or opposite to a polarization direction (or a poling direction) formed in the vibration layer 11 of the second vibration part 10B.

According to an embodiment of the present disclosure, the second electrode layer 15 of the first vibration part 10A and the second electrode layer 15 of the second vibration part 10B can be connected to each other, and thus, when a polarization direction (or a poling direction) formed in the vibration layer 11 of the first vibration part 10A is a direction which is different from or opposite to a polarization direction (or a poling direction) formed in the vibration layer 11 of the second vibration part 10B, the first vibration part 10A and the second vibration part 10B can be displaced (or vibrated or driven) in the same direction, and thus, a vibration width (or displacement width or driving width) of the vibration generating part 10 can be maximized, thereby enhancing a sound pressure level characteristic of the vibration generating part 10.

The vibration generating part 10 according to an embodiment of the present disclosure can further include a first cover member 30.

The first cover member 30 can be configured to protect one surface of the vibration generating part 10. For example, the one surface of the vibration generating part 10 can be a lower surface, a rear surface, a rearmost surface, a backside surface, or a backside portion. The first cover member 30 can be configured to protect a first surface of the vibration generating part 10. For example, the first surface of the vibration generating part 10 can be a lower surface, a rear surface, a rearmost surface, a backside surface, or a backside portion.

The first cover member 30 can be configured to cover the first vibration part 10A of the vibration generating part 10. For example, the first cover member 30 can be configured to cover the first electrode layer 13 of the first vibration part 10A. Accordingly, the first cover member 30 can protect the first surface of the vibration generating part 10 and the first electrode layer 13 of the first vibration part 10A.

The first cover member 30 according to an embodiment of the present disclosure can include an adhesive member. For example, the first cover member 30 can include a base cover member and an adhesive member which is in the base cover member and is connected or coupled to the first surface of the vibration generating part 10 and the first electrode layer 13 of the first vibration part 10A. For example, the adhesive member can include an electrical insulating material which has adhesive properties and is capable of compression and decompression.

According to another embodiment of the present disclosure, the first cover member 30 can be connected or coupled to the first surface of the vibration generating part 10 by an adhesive layer 40. For example, the first cover member 30 can be connected or coupled to at least a portion of the first electrode layer 13 of the first vibration part 10A or the first surface of the vibration generating part 10 by using a first adhesive layer 41. For example, the first cover member 30 can be connected or coupled to at least a portion of the first electrode layer 13 of the first vibration part 10A or the first surface of the vibration generating part 10 by a film laminating process by using the first adhesive layer 41.

The vibration generating part 10 according to an embodiment of the present disclosure can further include a second cover member 50.

The second cover member 50 can be configured to cover another surface of the vibration generating part 10. For example, another surface of the vibration generating part 10 can be an upper surface, an uppermost surface, a front surface, or a front portion. The second cover member 50 can be configured to cover a second surface of the vibration generating part 10. For example, the second surface of the vibration generating part 10 can be an upper surface, an uppermost surface, a front surface, or a front portion. The second cover member 50 can be configured to cover the second vibration part 10B of the vibration generating part 10. For example, the second cover member 50 can be configured to cover the second electrode layer 15 of the second vibration part 10B. Accordingly, the second cover member 50 can protect the second surface of the vibration generating part 10 and the second electrode layer 15 of the second vibration part 10B.

The second cover member 50 according to an embodiment of the present disclosure can include an adhesive member. For example, the second cover member 50 can include a base cover member and an adhesive member which is in the base cover member and is connected or coupled to the second surface of the vibration generating part 10 and the second electrode layer 15 of the first vibration part 10A. For example, the adhesive member can include an electrical insulating material which has adhesive properties and is capable of compression and decompression.

According to another embodiment of the present disclosure, the second cover member 50 can be connected or coupled to the second surface of the vibration generating part 10 by using the adhesive layer 40. For example, the second cover member 50 can be connected or coupled to at least a portion of the second electrode layer 15 of the second vibration part 10B or the second surface of the vibration generating part 10 by using a second adhesive layer 42. For example, the second cover member 50 can be connected or coupled to at least a portion of the second electrode layer 15 of the second vibration part 10B or the second surface of the vibration generating part 10 by a film laminating process by using the second adhesive layer 42.

Each of the first cover member 30 and the second cover member 50 according to an example embodiment of the present disclosure can include one or more materials of plastic, fiber, cloth, paper, leather, rubber, and wood, but embodiments of the present disclosure are not limited thereto. For example, the first cover member 30 and the second cover member 50 can include the same material or different materials. For example, each of the first cover member 30 and the second cover member 50 can be a polyimide film or a polyethylene terephthalate film, but embodiments of the present disclosure are not limited thereto.

The first adhesive layer 41 and the second adhesive layer 42 (or the adhesive layer 40) according to an embodiment of the present disclosure can include an electrical insulating material which has adhesive properties and is capable of compression and decompression. For example, the first adhesive layer 41 and the second adhesive layer 42 (or the adhesive layer 40) can include epoxy resin, acrylic resin, silicone resin, urethane resin, pressure sensitive adhesive (PSA), optically cleared adhesive (OCA), or optically cleared resin (OCR), but embodiments of the present disclosure are not limited thereto. For example, the first adhesive layer 41 and the second adhesive layer 42 (or the adhesive layer 40) can be configured to surround or fully surround the vibration generating part 10. The first adhesive layer 41 and the second adhesive layer 42 (or the adhesive layer 40) can be configured to cover or surround all surfaces of the vibration generating part 10. For example, the vibration generating part 10 can be inserted (or accommodated) into the adhesive layer 40, or can be buried in the adhesive layer 40.

According to an embodiment of the present disclosure, one of the first cover member 30 and the second cover member 50 can be omitted. For example, the first cover member 30 of the first cover member 30 and the second cover member 50 can be omitted. When the first cover member 30 is omitted, the first surface of the vibration generating part 10 can be covered or surrounded by the adhesive layer 40 or the first adhesive layer 41, and thus, the first surface of the vibration generating part 10 can be covered or protected by the adhesive layer 40 or the first adhesive layer 41. When the first cover member 30 is omitted, the second cover member 50 can be a cover member, a cover film, a protection member, or a protection film.

The vibration apparatus according to an embodiment of the present disclosure can further include a signal cable 90.

The signal cable 90 can be implemented to be connected to each of the first and second vibration parts 10A and 10B of the vibration generating part 10 at one side of the vibration generating part 10. The signal cable 90 can be inserted (or accommodated) between the first cover member 30 and the second cover member 50. The signal cable 90 can be connected to each of the first and second vibration parts 10A and 10B, between the first cover member 30 and the second cover member 50.

An end portion (or a distal end portion) of the signal cable 90 can be disposed at or inserted (or accommodated) into a portion between one periphery portion of the first cover member 30 and one periphery portion of the second cover member 50. The one periphery portion of the first cover member 30 and the one periphery portion of the second cover member 50 can accommodate or vertically cover a portion of the signal cable 90. Accordingly, the signal cable 90 can be provided as one body with the vibration generating part 10. For example, the vibration apparatus according to an example embodiment of the present disclosure can be a vibration apparatus which is provided as one body with the signal cable 90. For example, the signal cable 90 can be configured as a flexible cable, a flexible printed circuit cable, a flexible flat cable, a single-sided flexible printed circuit, a single-sided flexible printed circuit board (PCB), a flexible multilayer printed circuit, or a flexible multilayer PCB, but embodiments of the present disclosure are not limited thereto.

The signal cable 90 according to another embodiment of the present disclosure can include a base member 91 and a plurality of signal lines 92a, 92b, and 92c. For example, a plurality of signal lines 92a, 92b, and 92c can include a first signal line 92a, a second signal line 92b, a third signal line 92c.

The base member 91 can include a transparent or an opaque plastic material. For example, the base member 91 can include one or more of synthetic resins such as fluorine resin, polyimide-based resin, polyurethane-based resin, polyester-based resin, polyethylene-based resin, and polypropylene-based resin, but embodiments of the present disclosure are not limited thereto. The base member 91 can be a base film or a base insulation film, but embodiments of the present disclosure are not limited thereto.

Referring to FIG. 1, the base member 91 can have a certain width in a first direction X and can extend lengthwise along the second direction Y intersecting with the first direction X.

The first to third signal lines 92a to 92c can be disposed at a first surface of the base member 91 in parallel with the second direction Y and can be spaced apart or separated from each other in a first direction X. The first to third signal lines 92a to 92c can be disposed in parallel with the first surface of the base member 91. For example, each of the first to third signal lines 92a to 92c can be implemented in a line shape by patterning of a metal layer (or a conductive layer) formed or deposited on the first surface of the base member 91.

End portions (or distal end portions) of The first to third signal lines 92a to 92c can be separated from each other, and thus, can be individually curved or bent.

According to an embodiment of the present disclosure, referring to FIGS. 3 and 4, the first signal line 92a can be connected to the second electrode layer 15 of the first vibration part 10A, between the second vibration part 10B and the second cover member 50. For example, an end portion of the first signal line 92a can be disposed between the second cover member 50 and a second surface of the vibration generating part 10. For example, the end portion of the first signal line 92a can be configured to be electrically connected to an uppermost electrode layer (or a second electrode layer) 15 of the vibration generating part 10. For example, the end portion of the first signal line 92a electrically connected to the uppermost electrode layer (or the second electrode layer) 15 of the vibration generating part 10 can be covered by the adhesive layer 40 or the second adhesive layer 42, but embodiments of the present disclosure are not limited thereto. For example, the end portion of the first signal line 92a electrically connected to the uppermost electrode layer (or the second electrode layer) 15 of the vibration generating part 10 cannot be covered by the adhesive layer 40 or the second adhesive layer 42 and can contact or directly contact the second cover member 50. The end portion of the first signal line 92a can be electrically connected to at least a portion of the second electrode layer 15 of the second vibration part 10B which is the uppermost electrode layer 15. A signal applied to the first signal line 92a can be supplied to the second electrode layer 15 of the second vibration part 10B. Accordingly, the first signal line 92a can supply the second electrode layer 15 of the second vibration part 10B with a driving signal supplied from a vibration driving circuit.

According to an embodiment of the present disclosure, the second signal line 92b can be connected to the connection layer 20, between the first vibration part 10A and the second vibration part 10B. The second signal line 92b can be connected to the second electrode layer 15 of the first vibration part 10A, the first electrode layer 13 of the second vibration part 10B, and the connection layer 20, between the first vibration part 10A and the second vibration part 10B. An end portion of the second signal line 92b can be disposed between the first vibration part 10A and the second vibration part 10B. For example, the end portion of the second signal line 92b can be disposed between the second electrode layer 15 of the first vibration part 10A and the connection layer 20 or between the first electrode layer 13 of the second vibration part 10B and the connection layer 20. A signal applied to the second signal line 92b can be supplied to the second electrode layer 15 of the first vibration part 10A and the first electrode layer 13 of the second vibration part 10B through the connection layer 20. Therefore, the second signal line 92b can supply the driving signal, supplied from the vibration driving circuit, to the second electrode layer 15 of the first vibration part 10A and the first electrode layer 13 of the second vibration part 10B in common. Accordingly, in an embodiment of the present disclosure, two individual signal lines respectively connected to the second electrode layer 15 of the first vibration part 10A and the first electrode layer 13 of the second vibration part 10B cannot be configured, and the same signal can be applied to the second electrode layer 15 of the first vibration part 10A and the first electrode layer 13 of the second vibration part 10B by using one second signal line 92b.

According to an embodiment of the present disclosure, the third signal line 92c can be connected to the first electrode layer 13 of the first vibration part 10A, between the first vibration part 10A and the first cover member 30. For example, an end portion of the third signal line 92c can be disposed between the first cover member 30 and a first surface of the vibration generating part 10. For example, the end portion of the third signal line 92c can be configured to be electrically connected to a lowermost electrode layer (or a first electrode layer) 13 of the vibration generating part 10. For example, the end portion of the third signal line 92c electrically connected to the lowermost electrode layer (or the first electrode layer) 13 of the vibration generating part 10 can be covered by the adhesive layer 40 or the first adhesive layer 41, but embodiments of the present disclosure are not limited thereto. For example, the end portion of the third signal line 92c electrically connected to the lowermost electrode layer (or the first electrode layer) 13 of the vibration generating part 10 cannot be covered by the adhesive layer 40 or the second adhesive layer 42 and can contact or directly contact the first cover member 30. The end portion of the third signal line 92c can be electrically connected to at least a portion of the first electrode layer 13 of the first vibration part 10A which is the lowermost electrode layer 13.

In the first vibration part 10A, the first electrode layer 13 can receive the driving signal through the third signal line 92c, and the second electrode layer 15 can receive the driving signal through the second signal line 92b. Accordingly, the first vibration part 10A can alternately repeat contraction and/or expansion, based on an inverse piezoelectric effect which is generated from the driving signal by the vibration layer 11, and thus, can vibrate (or displace or drive).

In the second vibration part 10B, the first electrode layer 13 can receive the driving signal through the second signal line 92b, and the second electrode layer 15 can receive the driving signal through the first signal line 92a. Accordingly, the second vibration part 10B can alternately repeat contraction and/or expansion, based on an inverse piezoelectric effect which is generated from the driving signal by the vibration layer 11, and thus, can vibrate (or displace or drive).

Each of the first vibration part 10A and the second vibration part 10B can be flexed (or displaced or driven) in the same shape. Therefore, in the vibration generating part 10 or the vibration apparatus, a vibration width (or a displacement width or a driving width) of the first vibration part 10A and a vibration width (or a displacement width or a driving width) of the second vibration part 10B can be summated and maximized. For example, in the vibration generating part 10 or the vibration apparatus, a vibration of the first vibration part 10A and a vibration of the second vibration part 10B can be reinforced, and thus, vibration efficiency or vibration characteristic can be enhanced and a vibration width (or a displacement width or a driving width) can be maximized, whereby a sound characteristic and/or a sound pressure level characteristic of a low-pitched sound band can be enhanced.

The signal cable 90 can include first to third extension portions 91a, 91b, and 91c which respectively support the end portions (or distal end portions or one side) of the first to third signal lines 92a to 92c apart from one another. For example, each of the first to third extension portions 91a to 91c can be apart from one another between one edge portion of the first cover member 30 and one edge portion of the second cover member 50. Accordingly, the end portions (or distal end portions) of the first to third signal lines 92a to 92c can be apart from one another, and thus, can be individually bent or curved.

According to another embodiment of the present disclosure, each of the first to third extension portions 91a to 91c of the signal cable 90 can be omitted. For example, each of the first to third extension portions 91a to 91c can protrude or extend in a finger shape from the base member 91 and can be electrically connected to or contact corresponding electrode layers 13 and 15, between the one edge portion of the first cover member 30 and the one edge portion of the second cover member 50. For example, the end portions (or distal end portions or one side) of the first to third extension portions 91a to 91c can be electrically connected to or contact the corresponding electrode layers 13 and 15 by a conductive double-sided tape, and thus, an adhesive force to the corresponding electrode layers 13 and 15 can be secured.

The signal cable 90 according to an example embodiment of the present disclosure can further include an insulation member 93.

The insulation member 93 can be disposed at the first surface of the base member 91 to cover each of the first to third extension portions 91a to 91c other than the end portion of the signal cable 90. The insulation member 93 can be a protection layer, a coverlay, a coverlay layer, a cover film, an insulation film, or a solder mask, but embodiments of the present disclosure are not limited thereto.

The end portion (or distal end portion or one side) of the signal cable 90 inserted (or accommodated) between the first cover member 30 and the second cover member 50 can be inserted (or accommodated) and fixed between the first cover member 30 and the second cover member 50 through a film laminating process which uses the first adhesive layer 41 formed in the first cover member 30 and the second adhesive layer 42 formed in the second cover member 50. Therefore, the first signal line 92a can be maintained with being electrically connected to the first electrode layer 13 of the second vibration part 10B. Therefore, the second signal line 92b can be maintained with being electrically connected to the first electrode layer 13 of the second vibration part 10B and the second electrode layer 15 of the first vibration part 10A.

Moreover, the end portion (or distal end portion or one side) of the signal cable 90 can be inserted (or accommodated) and fixed between the first cover member 30 and the second cover member 50, and thus, a connection defect between the vibration generating part 10 and the signal cable 90 caused by the movement of the signal cable 90 can be prevented.

In the vibration apparatus according to an embodiment of the present disclosure, the first to third signal lines 92a and 92c of the signal cable 90 can be connected to the electrode layer of the vibration generating part 10 between the first cover member 30 and the second cover member 50, and thus, a soldering process for an electrical connection between the vibration generating part 10 and the signal cable 90 cannot be needed, thereby simplifying a structure and a manufacturing process of a vibration apparatus. Also, the vibration apparatus according to another embodiment of the present disclosure can include the plurality of vibration parts 10A and 10B which overlap or overlay each other to vibrate (or displace or drive) in the same direction, and thus, vibration efficiency or vibration characteristic can be enhanced and a vibration width (or a displacement width or a driving width) can be maximized, thereby enhancing a sound characteristic and/or a sound pressure level characteristic of a pitched sound band including the low-pitched sound band.

In the vibration apparatus according to an embodiment of the present disclosure, the connection layer 20 can be configured between the first vibration part 10A and the second vibration part 10B, and the connection layer 20 can be configured with a soldering foil. For example, in a case where the vibration generating part 10 is configured by simultaneously sintering the electrode layers 13 and 15 and the vibration layer 11, the electrode layers 13 and 15 capable of being applied to a high temperature (for example, 900° C. or more) which is a sintering temperature should be configured. Accordingly, in an embodiment of the present disclosure, because the connection layer 20 is configured by welding, an adhesive force between the first vibration part 10A and the second vibration part 10B can be enhanced, and a thickness of the vibration apparatus 10 can decrease.

Moreover, in the vibration apparatus according to an embodiment of the present disclosure, because the connection layer 20 is configured with a soldering foil having a melting point which is 400° C. or less, a process temperature can decrease, a process can be simplified, a process time can be reduced, and the productivity of a vibration apparatus can be enhanced.

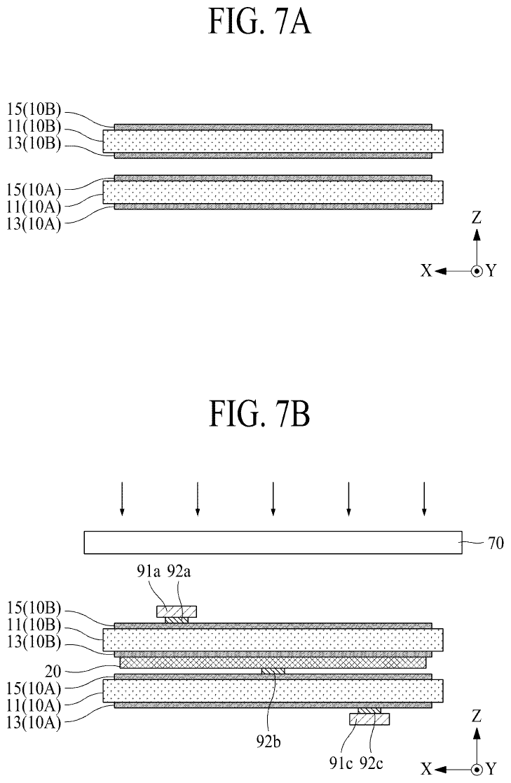

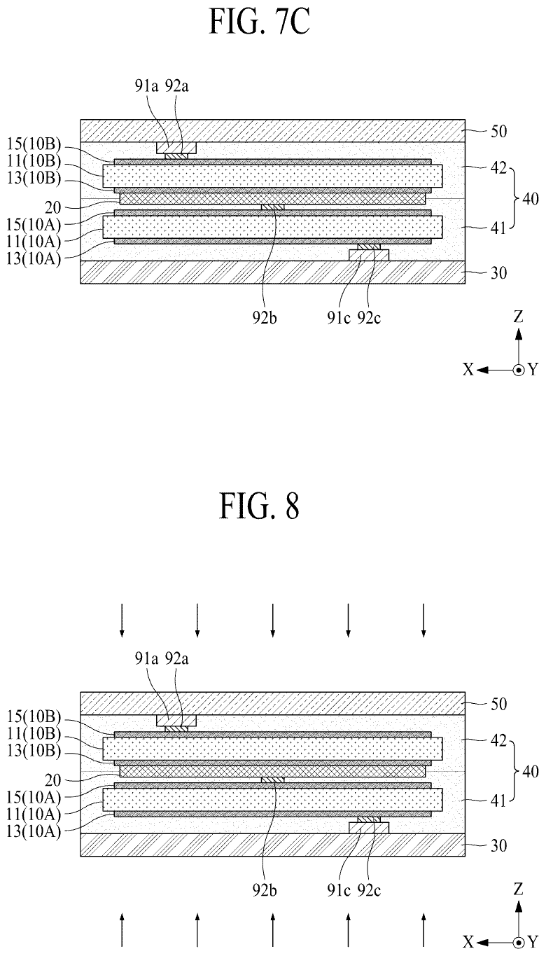

FIGS. 7A to 7C are diagrams illustrating a method of manufacturing the vibration apparatus illustrated in FIG. 1 according to an embodiment of the present disclosure. FIGS. 7A to 7C are diagrams illustrating a method of manufacturing the vibration apparatus according to an embodiment of the present disclosure described above with reference to FIGS. 1 to 6. Hereinafter, therefore, like reference numerals refer to like elements, and repeated descriptions will be briefly given or are omitted.

Referring to FIGS. 7A to 7C, a method of manufacturing a vibration apparatus according to an embodiment of the present disclosure can include a step of configuring a plurality of vibration parts 10A and 10B, a step of configuring a connection layer 20 between the plurality of vibration parts 10A and 10B, a step of configuring a signal cable 90 electrically connected to the plurality of vibration parts 10A and 10B, and a step of configuring first and second cover members 30 and 50.

Referring to FIG. 7A, the step of configuring the plurality of vibration parts (for example, first and second vibration parts) 10A and 10B can include a step of configuring a vibration layer 11. For example, the vibration layer 11 can include a piezoelectric material (or an electro active material) including a piezoelectric effect. For example, the vibration layer 11 can be configured to a width of 6 cm, a height of 12 cm, and a thickness of 165 μm, but embodiments of the present disclosure are not limited thereto.

Subsequently, a first electrode 13 can be configured at a first surface (or a lower surface) of the vibration layer 11 of each of first and second vibration parts 10A and 10B, and a second electrode layer 15 can be configured at a second surface (or an upper surface).

According to an embodiment of the present disclosure, a metal paste including silver (Ag) can be coated on a region, where an electrode layer is to be disposed, of each of the first surface and the second surface, and then, by firing the coated metal paste, each of the first electrode layer 13 and the second electrode layer 15 can be formed. For example, the firing can be performed for about 15 minutes at a temperate of 650° C. to 700° C., but embodiments of the present disclosure are not limited thereto. For example, the firing can include a process of performing natural cooling after being maintained for about 15 minutes at a temperate of 650° C. to 700° C., but embodiments of the present disclosure are not limited thereto. A process time can include a thermal treatment time and a natural cooling time and can be performed for about 1 hour, but embodiments of the present disclosure are not limited thereto. For example, the metal paste including silver (Ag) can be formed to have a thickness of 5 μm or less, but embodiments of the present disclosure are not limited thereto.

Referring to FIG. 7B, in an embodiment of the present disclosure, the step of configuring the connection layer 20 between the plurality of vibration parts 10A and 10B and the step of configuring the signal cable 90 electrically connected to the plurality of vibration parts 10A and 10B can be simultaneously performed.

First, the connection layer 20 can be disposed between the plurality of vibration parts 10A and 10B and can connect the signal cable 90 to a plurality of vibration parts 10A. For example, the connection layer 20 can be disposed between a second electrode layer 15 of the first vibration part 10A and a first electrode layer 13 of the second vibration part 10B. For example, a first signal line 92a can be connected to a second electrode layer 15 of the second vibration part 10B, a second signal line 92b can be connected between the connection layer 20 and the second electrode layer 15 of the first vibration part 10A, and a third signal line 92c can be connected to a first electrode layer 13 of the first vibration part 10A.

Subsequently, in an embodiment of the present disclosure, a pressure apparatus 70 can be disposed on the second vibration part 10B, a load of about 0.2 kg or more can be applied in an arrow direction, and thermal treatment can be performed on the connection layer 20 at a temperature of 400° C. or less. For example, a process of performing thermal treatment on the connection layer 20 at a temperature of 400° C. or less can be a firing step. For example, the firing step can be a thermal treatment process. For example, the firing step can be a step of melting a soldering foil disposed between the electrode layers 13 and 15 to weld the melted soldering foil between the first vibration part 10A and the second vibration part 10B. For example, a melting point of the soldering foil used as the connection layer 20 can be a range of about 100° C. to about 400° C. For example, a time for welding the soldering foil can be less than 1 hour, but embodiments of the present disclosure are not limited thereto. For example, the soldering foil can be welded for 5 minutes at about 150° C. However, embodiments of the present disclosure are not limited thereto. According to an embodiment of the present disclosure, the melted soldering foil can include a uniform surface, and as the melted soldering foil is cooled at a room temperature, the melted soldering foil can be welded to configure the connection layer 20. For example, the connection layer 20 can have a thickness of several μm to tens μm, but embodiments of the present disclosure are not limited thereto. According to an embodiment of the present disclosure, a welded connection layer 20 can be configured, and thus, the first vibration part 10A and the second vibration part 10B can be easily connected to each other at a relatively low temperature.

Referring to FIG. 7C, the step of configuring first and second cover members 30 and 50 can be a step of configuring the first cover member 30 at a first surface of the vibration generating part 10 and configuring the second cover member 50 at a second surface of the vibration generating part 10.

First, a first adhesive layer 41 can be formed (or coated) at the first cover member 30, the vibration generating part 10 can be disposed on a first adhesive layer 41, and a second adhesive layer 42 can be formed (or coated) at the second surface of the vibration generating part 10. Accordingly, the vibration generating part 10 can be surrounded by the first adhesive layer 41 and the second adhesive layer 42, or can be buried (or accommodated) in an adhesive layer 40 including the first adhesive layer 41 and the second adhesive layer 42.

Subsequently, the second cover member 50 can be attached to the second surface of the vibration generating part 10. The second cover member 50 can be connected or coupled to the second surface of the vibration generating part 10 by using a lamination process using the second adhesive layer 42. Accordingly, the vibration generating part 10 can be disposed between the first cover member 30 and the second cover member 50 and can be protected by the first cover member 30 and the second cover member 50.

According to an embodiment of the present disclosure, the welded connection layer 20 can be configured between the first and second vibration parts 10A and 10B, and the connection layer 20 can be a soldering foil having a melting point of 400° C. or less. Accordingly, a thickness and a weight of the vibration apparatus 10 can be reduced compared to a process of individually manufacturing and stacking each of the first and second vibration parts 10A and 10B.

According to an embodiment of the present disclosure, comparing with the process of individually manufacturing and stacking each of the first and second vibration parts 10A and 10B, a damping phenomenon can be reduced between the first and second vibration parts 10A and 10B, and thus, a sound pressure level of the vibration apparatus 10 can be enhanced.

Moreover, according to an embodiment of the present disclosure, comparing with a process of stacking and simultaneously sintering an electrode layer and a vibration layer, the method of manufacturing the vibration apparatus can be simple in process, can stacking the first and second vibration parts 10A and 10B at a low temperature, can decrease a process time, and can enhance productivity.

FIG. 8 is a diagram illustrating a method of manufacturing the vibration apparatus illustrated in FIG. 1 according to another embodiment of the present disclosure. FIG. 8 is a diagram illustrating a method of manufacturing the vibration apparatus according to another embodiment of the present disclosure described above with reference to FIGS. 1 to 6. Except for that the connection layer 20, the signal cable 90, and the first and second cover members 30 and 50 are simultaneously configured, the method of manufacturing the vibration apparatus according to another embodiment of the present disclosure can be substantially the same as an embodiment of the present disclosure described above with reference to FIGS. 7A to 7C. Hereinafter, therefore, like reference numerals refer to like elements, and repeated descriptions will be briefly given or are omitted.

Referring to FIG. 8, the method of manufacturing the vibration apparatus according to another embodiment of the present disclosure can simultaneously perform a step of configuring a connection layer 20 between a plurality of vibration parts 10A and 10B, a step of configuring a signal cable 90 electrically connected to the plurality of vibration parts 10A and 10B, and a step of configuring first and second cover members 30 and 50.

First, the connection layer 20 can be disposed between the plurality of vibration parts 10A and 10B, and the signal cable 90 can be connected to a plurality of vibration parts 10A. Also, a first adhesive layer 41 and a first cover member 30 can be disposed at a first surface of the vibration generating part 10, and a second adhesive layer 42 and a second cover member 50 can be disposed at a second surface of the vibration generating part 10.

Subsequently, in another embodiment of the present disclosure, the vibration generating part 10, the connection layer 20, the signal cable 90, and the first and second cover members 30 and 50 can be bonded to each other at a temperature of 200° C. or less. For example, the bonding can be performed by applying pressure in an arrow direction at the first surface and the second surface of the vibration generating part 10. For example, the bonding can be performed at a relatively low temperature. For example, low temperature bonding can be performed at about 120° C. For example, the low temperature bonding can be primary bonding.

Subsequently, polarization (or poling) can be performed by applying a high voltage to the first and second vibration parts 10A and 10B. For example, polarization (or poling) can be performed by applying a high voltage of about 3 kV/μm to the first and second vibration parts 10A and 10B.

Subsequently, an ultrasound signal can be applied to the first vibration part 10A and the second vibration part 10B. For example, as heat and/or the ultrasound signal are/is applied to the first vibration part 10A and the second vibration part 10B, heat can occur in the first vibration part 10A and the second vibration part 10B. At this time, heat and/or the ultrasound signal can be applied to the connection layer 20 including a soldering foil, and ultrasound soldering (or ultrasound welding) can be performed. For example, the ultrasound soldering can be secondary bonding. Therefore, the welded connection layer 20 can be configured between the first vibration part 10A and the second vibration part 10B. Accordingly, the first vibration part 10A and the second vibration part 10B can be easily connected to each other.

A manufacturing method according to another embodiment of the present disclosure can weld a soldering foil by using heat and an ultrasound and can thus perform a process at a low temperature. Accordingly, the manufacturing method according to another embodiment of the present disclosure can increase process efficiency.

Another embodiment of the present disclosure can have substantially the same effect as an embodiment of the present disclosure described above with reference to FIGS. 7A and 7C. Also, the manufacturing method according to another embodiment of the present disclosure can be simpler in process, can additionally reduce a process time, and can more enhance productivity.

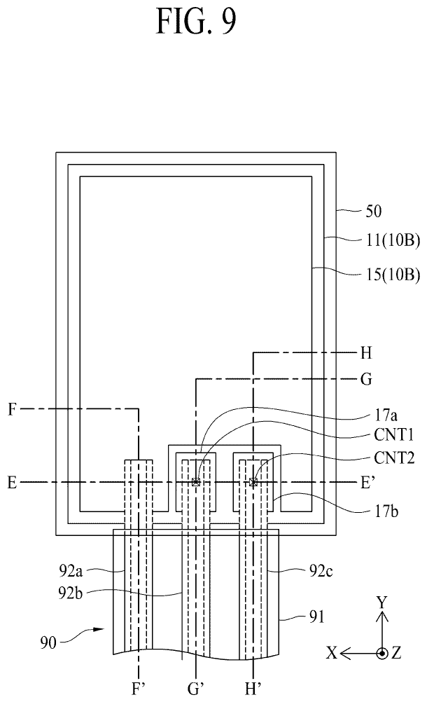

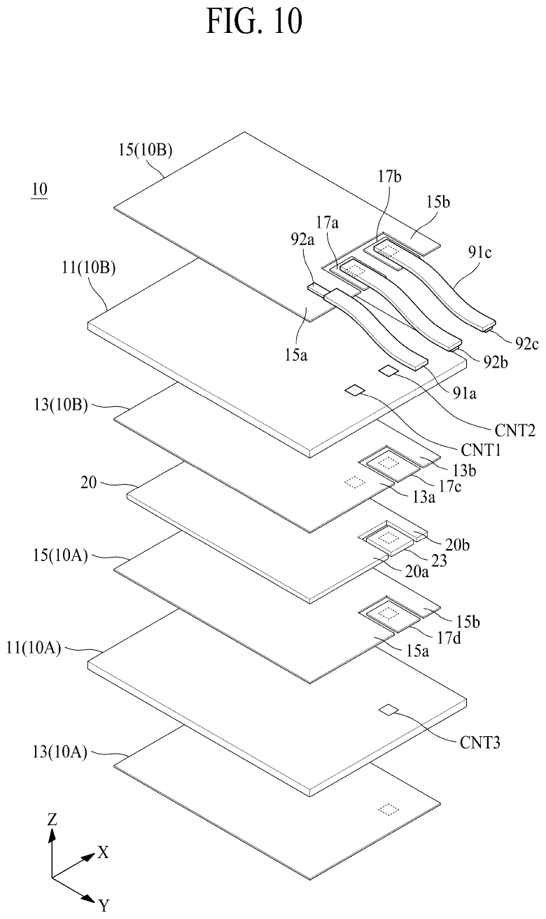

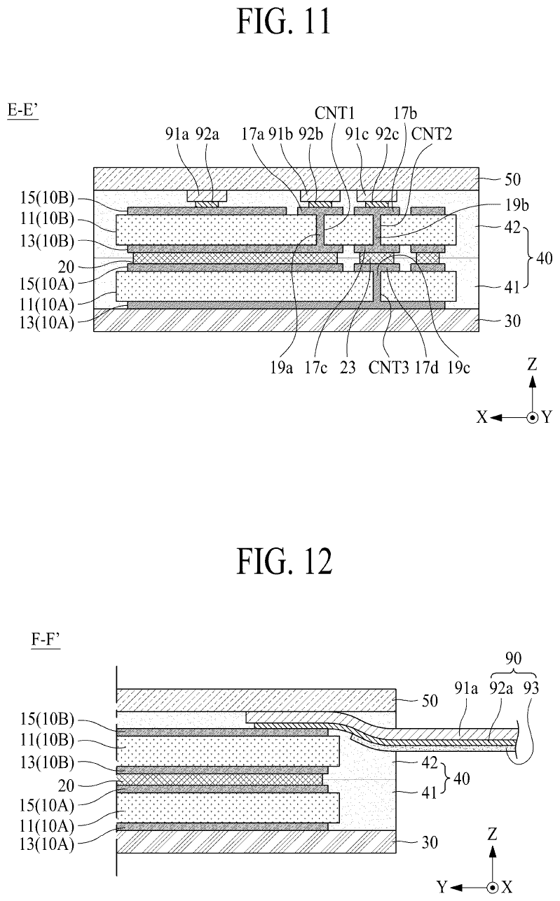

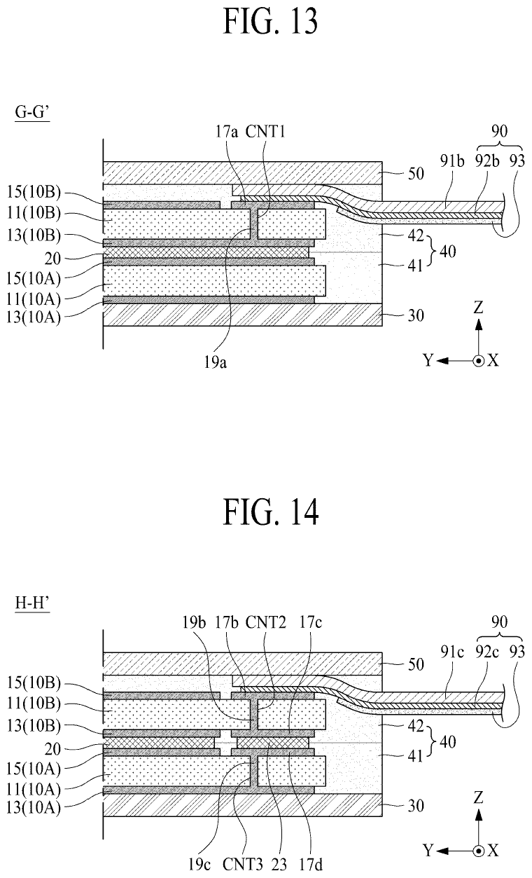

FIG. 9 is a diagram illustrating a vibration apparatus according to another embodiment of the present disclosure. FIG. 10 is an exploded perspective view illustrating a connection structure between a vibration generating part and a signal cable illustrated in FIG. 9 according to another embodiment of the present disclosure. FIG. 11 is a cross-sectional view taken along line E-E′ illustrated in FIG. 9 according to an embodiment of the present disclosure. FIG. 12 is a cross-sectional view taken along line F-F′ illustrated in FIG. 9 according to an embodiment of the present disclosure. FIG. 13 is a cross-sectional view taken along line G-G′ illustrated in FIG. 9 according to an embodiment of the present disclosure. FIG. 14 is a cross-sectional view taken along line H-H′ illustrated in FIG. 9 according to an embodiment of the present disclosure. Another embodiment of the present disclosure described above with reference to FIGS. 9 to 14 can be an embodiment where one or more contact holes are configured in a vibration layer 11, and as the contact hole is configured, a connection structure of a signal cable is changed, and an auxiliary electrode layer, a connection part, and an auxiliary connection layer are additionally configured. The other elements except the elements can be substantially the same as an embodiment of the present disclosure described above with reference to FIGS. 1 to 6. Hereinafter, therefore, like reference numerals refer to like elements, and repeated descriptions will be briefly given or are omitted.

Referring to FIGS. 9 to 14, each of a first vibration part 10A and a second vibration part 10B according to another embodiment of the present disclosure can include a vibration layer 11, a first electrode layer 13, and a second electrode layer 15.

In the first vibration part 10A, the vibration layer 11 can include a contact hole which is configured in one end (or one side) of the vibration layer 11. For example, the contact hole configured in the one end (or one side) of the vibration layer 11 can be a third contact hole CNT3. For example, the third contact hole CNT3 can be configured adjacent to a signal cable described below.

The first electrode layer 13 can be configured at a first surface (or a lower surface) of the vibration layer 11. The second electrode layer 15 can be configured at a second surface (or an upper surface) of the vibration layer 11. The second electrode layer 15 can include a plurality of protrusion portions (or a pair of protrusion portions) 15a and 15b which protrude from one end (or one side) thereof. The plurality of protrusion portions 15a and 15b can be disposed apart from each other in parallel. Accordingly, the second electrode layer 15 cannot be configured in a region where the plurality of protrusion portions 15a and 15b are spaced apart from each other, and the second surface (or the upper surface) of the vibration layer 11 can be exposed.

In another embodiment of the present disclosure, in the first vibration part 10A, the second electrode layer 15 can include a concave portion which is concave from a portion of one end (or one side) thereof. The concave portion can be formed to be concave in a second direction Y from a center portion of the one end (or one side) of the second electrode layer 15. For example, the concave portion can be concavely formed to have a certain length in the second direction Y from the center portion of the one end (or one side) of the second electrode layer 15. For example, the concave portion can be configured between the plurality of protrusion portions (or the pair of protrusion portions) 15a and 15b, but embodiments of the present disclosure are not limited thereto. For example, the concave portion can be a portion from which a portion of the second electrode layer 15 is removed or where the second electrode layer 15 is not formed. For example, the concave portion can be a patterning portion, an electrode non-formation portion, an electrode non-disposition portion, or an open portion, but embodiments of the present disclosure are not limited thereto.

In the second vibration part 10B, the vibration layer 11 can include a plurality of contact holes which are configured in the one end of the vibration layer 11. Each of the plurality of contact holes can be configured adjacent to the signal cable 90. For example, the plurality of contact holes configured in the one end of the vibration layer 11 can include a first contact hole CNT1 and a second contact hole CNT2. The first contact hole CNT1 and the second contact hole CNT2 can be disposed apart from each other by a certain distance. For example, the first contact hole CNT1 cannot overlap a third contact hole CNT3 which is configured in the vibration layer 11 of the first vibration part 10A. For example, the second contact hole CNT2 can overlap the third contact hole CNT3 which is configured in the vibration layer 11 of the first vibration part 10A.

In the second vibration part 10B, the first electrode layer 13 can be configured at the first surface (or the lower surface) of the vibration layer 11. For example, the first electrode layer 13 can include a plurality of protrusion portions (or a pair of protrusion portions) 13a and 13b which protrude from one end (or one side) thereof. The plurality of protrusion portions 13a and 13b can be disposed apart from each other in parallel. Accordingly, the first electrode layer 13 cannot be configured in a region where the plurality of protrusion portions 13a and 13b are spaced apart from each other, and the first surface (or the lower surface) of the vibration layer 11 can be exposed.

In another embodiment of the present disclosure, in the second vibration part 10B, the first electrode layer 13 can include a concave portion which is concave from a portion of one end (or one side) thereof. The concave portion can be formed to be concave in the second direction Y from a center portion of the one end (or one side) of the first electrode layer 13. For example, the concave portion can be concavely formed to have a certain length in the second direction Y from the center portion of the one end (or one side) of the first electrode layer 13. For example, the concave portion can be configured between the plurality of protrusion portions (or the pair of protrusion portions) 13a and 13b, but embodiments of the present disclosure are not limited thereto. For example, the concave portion can be a portion from which a portion of the first electrode layer 13 is removed or where the first electrode layer 13 is not formed. For example, the concave portion can be a patterning portion, an electrode non-formation portion, an electrode non-disposition portion, or an open portion, but embodiments of the present disclosure are not limited thereto.

In the second vibration part 10B, the second electrode layer 15 can be configured at the second surface (or the upper surface) of the vibration layer 11. For example, the second electrode layer 15 can include a plurality of protrusion portions (or a pair of protrusion portions) 15a and 15b which protrude from one end (or one side) thereof. The plurality of protrusion portions 15a and 15b can be disposed apart from each other in parallel. Accordingly, the second electrode layer 15 cannot be configured in a region where the plurality of protrusion portions 15a and 15b are spaced apart from each other, and the second surface (or the upper surface) of the vibration layer 11 can be exposed.

In another embodiment of the present disclosure, in the second vibration part 10B, the second electrode layer 15 can include a concave portion which is concave from a portion of one end (or one side) thereof. The concave portion can be formed to be concave in the second direction Y from a center portion of the one end (or one side) of the second electrode layer 15. For example, the concave portion can be concavely formed to have a certain length in the second direction Y from the center portion of the one end (or one side) of the second electrode layer 15. For example, the concave portion can be configured between the plurality of protrusion portions (or the pair of protrusion portions) 15a and 15b, but embodiments of the present disclosure are not limited thereto. For example, the concave portion can be a portion from which a portion of the second electrode layer 15 is removed or where the second electrode layer 15 is not formed. For example, the concave portion can be a patterning portion, an electrode non-formation portion, an electrode non-disposition portion, or an open portion, but embodiments of the present disclosure are not limited thereto.

According to an embodiment of the present disclosure, the first electrode layer 13 of the first vibration part 10A cannot include a plurality of protrusion portions, and the second electrode layer 15 of the first vibration part 10A can include the plurality of protrusion portions 15a and 15b. Accordingly, the first electrode layer 13 and the second electrode layer 15 of the first vibration part 10A can have different shapes.

According to an embodiment of the present disclosure, the first electrode layer 13 of the second vibration part 10B and the second electrode layer 15 of the second vibration part 10B can have different shapes. For example, the plurality of protrusion portions 13a and 13b configured in the first electrode layer 13 of the second vibration part 10B and the plurality of protrusion portions 15a and 15b configured in the second electrode layer 15 of the second vibration part 10B can have a non-overlap region where the elements do not overlap each other. For example, a partial region of the plurality of protrusion portions 13a and 13b configured in the first electrode layer 13 of the second vibration part 10B and a partial region of the plurality of protrusion portions 15a and 15b configured in the second electrode layer 15 of the second vibration part 10B cannot overlap each other. For example, the concave portion configured in the first electrode layer 13 of the second vibration part 10B and the concave portion configured in the second electrode layer 15 of the second vibration part 10B can have a non-overlap region where the elements do not overlap each other. For example, a partial region of the concave portion configured in the first electrode layer 13 of the second vibration part 10B and a partial region of the concave portion configured in the second electrode layer 15 of the second vibration part 10B cannot overlap each other.

According to an embodiment of the present disclosure, the second electrode layer 15 of the first vibration portion 10A and the first electrode layer 13 of the second vibration portion 10B can have the same shape. For example, a plurality of protrusion portions 15a and 15b configured in the second electrode layer 15 of the first vibration portion 10A and a plurality of protrusion portions 13a and 13b configured in the first electrode layer 13 of the second vibration portion 10B can overlap each other. For example, a concave portion configured in the second electrode layer 15 of the first vibration portion 10A and a concave portion configured in the first electrode layer 13 of the second vibration portion 10B can overlap each other.

According to an embodiment of the present disclosure, the vibration generating part 10 can further include first to fourth auxiliary electrode layers 17a to 17d. The first to third auxiliary electrode layers 17a to 17c can be configured in the vibration generating part 10 or the second vibration part 10B. The fourth auxiliary electrode layer 17d can be configured in the vibration generating part 10 or the first vibration part 10A.

In the second vibration part 10B, the first auxiliary electrode layer 17a can be configured (or formed) on the vibration layer 11 so as to be electrically disconnected from the second electrode layer 15. The first auxiliary electrode layer 17a can be configured (or formed) at a second surface (or an upper surface) of the vibration layer 11 so as to be electrically disconnected from the second electrode layer 15. For example, the first auxiliary electrode layer 17a can be configured (or formed) on the vibration layer 11 between the plurality of protrusion portions 15a and 15b of the second electrode layer 15. The first auxiliary electrode layer 17a can overlap the first electrode layer 13 of the second vibration part 10B.

In the second vibration part 10B, the first auxiliary electrode layer 17a can be electrically connected to the first electrode layer 13 through the vibration layer 11. For example, the first auxiliary electrode layer 17a can be electrically connected to the first electrode layer 13 through a first connection part 19a configured (or formed) in the vibration layer 11. For example, the first connection part 19a can be filled in the first contact hole CNT1 configured (or formed) in the vibration layer 11. According to an embodiment of the present disclosure, the first connection part 19a can be configured as a material used as an electrode layer is filled in the first contact hole CNT1 in a process of forming the first auxiliary electrode layer 17a and the first electrode layer 13. Therefore, the first auxiliary electrode layer 17a can be electrically connected to the first electrode layer 13. For example, the first auxiliary electrode layer 17a can include the same material as that of the second electrode layer 15 of the second vibration part 10B and can be configured by using the same process, but embodiments of the present disclosure are not limited thereto.

In the second vibration part 10B, the second auxiliary electrode layer 17b can be configured (or formed) on the vibration layer 11 so as to be electrically disconnected from the second electrode layer 15. The second auxiliary electrode layer 17b can be configured (or formed) at a second surface (or an upper surface) of the vibration layer 11 so as to be electrically disconnected from the second electrode layer 15. For example, the second auxiliary electrode layer 17b can be configured (or formed) on the vibration layer 11 between the plurality of protrusion portions 15a and 15b of the second electrode layer 15. The second auxiliary electrode layer 17b can be configured (or formed) at the second surface (or the upper surface) of the vibration layer 11 so as to be electrically disconnected from the first auxiliary electrode layer 17a. The second auxiliary electrode layer 17b cannot overlap the first electrode layer 13 of the second vibration part 10B.

In the second vibration part 10B, the second auxiliary electrode layer 17b can be electrically connected to the third auxiliary electrode layer 17c configured at the first surface (or the lower surface) of the vibration layer 11 through the vibration layer 11. For example, the second auxiliary electrode layer 17b can be electrically connected to the third auxiliary electrode layer 17c through a second connection part 19b configured (or formed) in the vibration layer 11. For example, the second connection part 19b can be filled in the second contact hole CNT2 configured (or formed) in the vibration layer 11. The second contact hole CNT2 can overlap the second auxiliary electrode layer 17b and the third auxiliary electrode layer 17c. According to an embodiment of the present disclosure, the second connection part 19b can be configured as a material used as an electrode layer is filled in the second contact hole CNT2 in a process of forming the second auxiliary electrode layer 17b and the third auxiliary electrode layer 17c. Therefore, the second auxiliary electrode layer 17b can be electrically connected to the third auxiliary electrode layer 17c. For example, the second auxiliary electrode layer 17b can include the same material as that of the second electrode layer 15 of the second vibration part 10B and can be configured by using the same process, but embodiments of the present disclosure are not limited thereto.

In the second vibration part 10B, the third auxiliary electrode layer 17c can be configured (or formed) on the vibration layer 11 so as to be electrically disconnected from the first electrode layer 13. The third auxiliary electrode layer 17c can be configured (or formed) at the first surface (or the lower surface) of the vibration layer 11 so as to be electrically disconnected from the first electrode layer 13. For example, the third auxiliary electrode layer 17c can be configured (or formed) on the vibration layer 11 between the plurality of protrusion portions 13a and 13b of the first electrode layer 13.

In the second vibration part 10B, the third auxiliary electrode layer 17c can be electrically connected to the second auxiliary electrode layer 17b configured at the second surface (or the upper surface) of the vibration layer 11 through the vibration layer 11. For example, the third auxiliary electrode layer 17c can be electrically connected to the second auxiliary electrode layer 17b through the second connection part 19b configured (or formed) in the vibration layer 11. For example, the third auxiliary electrode layer 17c can include the same material as that of the first electrode layer 13 of the second vibration part 10B and can be configured by using the same process, but embodiments of the present disclosure are not limited thereto.

In the first vibration part 10A, the fourth auxiliary electrode layer 17d can be configured (or formed) on the vibration layer 11 so as to be electrically disconnected from the second electrode layer 15. The fourth auxiliary electrode layer 17d can be configured (or formed) at the second surface (or the upper surface) of the vibration layer 11 so as to be electrically disconnected from the second electrode layer 15. For example, the fourth auxiliary electrode layer 17d can be configured (or formed) on the vibration layer 11 between the plurality of protrusion portions 15a and 15b of the second electrode layer 15.

In the first vibration part 10A, the fourth auxiliary electrode layer 17d can be electrically connected to the first electrode layer 13 configured at the first surface (or the lower surface) of the vibration layer 11 through the vibration layer 11. For example, the fourth auxiliary electrode layer 17d can be electrically connected to the first electrode layer 13 through a third connection part 19c configured (or formed) in the vibration layer 11. For example, the third connection part 19c can be filled in the third contact hole CNT3 configured (or formed) in the vibration layer 11. The third contact hole CNT3 can overlap the second auxiliary electrode layer 17b, the second contact hole CNT2 of the second vibration part 10B, the second connection part 19b, the third auxiliary electrode layer 17c, and the first electrode layer 13. According to an embodiment of the present disclosure, the third connection part 19c can be configured as a material used as an electrode layer is filled in the third contact hole CNT3 in a process of forming the fourth auxiliary electrode layer 17d and the first electrode layer 13. Therefore, the fourth auxiliary electrode layer 17d can be electrically connected to the first electrode layer 13. For example, the fourth auxiliary electrode layer 17d can include the same material as that of the first electrode layer 13 of the first vibration part 10A and can be configured by using the same process, but embodiments of the present disclosure are not limited thereto.

According to an embodiment of the present disclosure, the connection layer 20 can be configured between the first vibration part 10A and the second vibration part 10B. The connection layer 20 can include a plurality of protrusion portions (or a pair of protrusion portions) 20a and 20b which protrude from one end (or one side) thereof. The plurality of protrusion portions 20a and 20b can be disposed apart from each other in parallel. Accordingly, the connection layer 20 cannot be configured in a region where the plurality of protrusion portions 20a and 20b are spaced apart from each other.

In another embodiment of the present disclosure, the connection layer 20 can include a concave portion which is concave from a portion of one end (or one side) of the connection layer 20. The concave portion can be formed to be concave in the second direction Y from a center portion of the one end (or one side) of the connection layer 20. For example, the concave portion can be concavely formed to have a certain length in the second direction Y from the center portion of the one end (or one side) of the connection layer 20. For example, the concave portion can be configured between the plurality of protrusion portions (or the pair of protrusion portions) 20a and 20b, but embodiments of the present disclosure are not limited thereto. For example, the concave portion can be a portion where the connection layer 20 is not formed, and thus, can be a patterning portion or an open portion, but embodiments of the present disclosure are not limited thereto.

According to an embodiment of the present disclosure, the connection layer 20 can connect the second electrode layer 15 of the first vibration part 10A to the first electrode layer 13 of the second vibration part 10B. The first electrode layer 13 of the second vibration part 10B can be connected to the first auxiliary electrode layer 17a by using the first connection part 19a. Accordingly, the first auxiliary electrode layer 17a, the first connection part 19a, the first electrode layer 13 of the second vibration part 10B, the connection layer 20, and the second electrode layer 15 of the first vibration part 10A can be connected to each other.

According to an embodiment of the present disclosure, an auxiliary connection layer 23 can be configured between the plurality of protrusion portions (or the pair of protrusion portions) 20a and 20b protruding (or extending) from the one end (or one side) of the connection layer 20. For example, the auxiliary connection layer 23 can be spaced apart from the connection layer 20, in the same layer as the connection layer 20. For example, the auxiliary connection layer 23 can be disposed at the concave portion configured between the plurality of protrusion portions (or the pair of protrusion portions) 20a and 20b.

According to an embodiment of the present disclosure, the auxiliary connection layer 23 can be configured between the third auxiliary electrode layer 17c and the fourth auxiliary electrode layer 17d and can connect the third auxiliary electrode layer 17c to the fourth auxiliary electrode layer 17d. The auxiliary connection layer 23 can overlap the third auxiliary electrode layer 17c and the fourth auxiliary electrode layer 17d. According to an embodiment of the present disclosure, because the auxiliary connection layer 23 connects the third auxiliary electrode layer 17c to the fourth auxiliary electrode layer 17d, the second auxiliary electrode layer 17b, the second connection part 19b, the third auxiliary electrode layer 17c, the auxiliary connection layer 23, the fourth auxiliary electrode layer 17d, the third connection part 19c, and the first electrode layer 13 of the first vibration part 10A can be electrically connected to each other. For example, the auxiliary connection layer 23 can include the same material as that of the connection layer 20 and can be configured by using the same process, but embodiments of the present disclosure are not limited thereto. For example, the auxiliary connection layer 23 can include the same soldering foil as that of the connection layer 20.

According to an embodiment of the present disclosure, the first auxiliary electrode layer 17a can be connected to the first electrode layer 13 of the second vibration part 10B through the first connection part 19a. The first electrode layer 13 of the second vibration part 10B can be connected to the second electrode layer 15 of the first vibration part 10A through the connection layer 20. Therefore, the first auxiliary electrode layer 17a, the first connection part 19a, the first electrode layer 13 of the second vibration part 10B, the connection layer 20, the first electrode layer 13 of the second vibration part 10B can be sequentially connected to each other. For example, the second electrode layer 15 of the first vibration part 10A and the first electrode layer 13 of the second vibration part 10B can be a middle electrode layer, an internal electrode layer, and a common electrode layer of the vibration generating part 10, but embodiments of the present disclosure are not limited thereto.

According to an embodiment of the present disclosure, the second auxiliary electrode layer 17b can be connected to the third auxiliary electrode layer 17c through the second connection part 19b, the third auxiliary electrode layer 17c can be connected to the fourth auxiliary electrode layer 17d through the auxiliary connection layer 23, and the fourth auxiliary electrode layer 17d can be connected to the first electrode layer 13 of the first vibration part 10A through the third connection part 19c. Accordingly, the second auxiliary electrode layer 17b, the second connection part 19b, the third auxiliary electrode layer 17c, the auxiliary connection layer 23, the fourth auxiliary electrode layer 17d, the third connection part 19c, and the first electrode layer 13 of the first vibration part 10A can be sequentially connected to each other.

According to an embodiment of the present disclosure, the signal cable 90 can be accommodated between the first cover member 30 and the second cover member 50. The signal cable 90 can be accommodated between the second vibration part 10B and the second cover member 50. The signal cable 90 can include first to third signal lines 92a to 92c electrically connected to the vibration generating part 10. The first to third signal lines 92a to 92c can be accommodated between the second vibration part 10B and the second cover member 50.

According to an embodiment of the present disclosure, the first signal line 92a can be electrically connected to the second electrode layer 15 of the second vibration part 10B, between the second vibration part 10B and the second cover member 50. A signal applied to the first signal line 92a can be supplied to the second electrode layer 15 of the second vibration part 10B. Accordingly, the first signal line 92a can supply the second electrode layer 15 of the second vibration part 10B with a driving signal supplied from a vibration driving circuit.

According to an embodiment of the present disclosure, the second signal line 92b can be connected to the first auxiliary electrode layer 17a, between the second vibration part 10B and the second cover member 50. A signal applied to the second signal line 92b can be supplied to the first electrode layer 13 of the second vibration part 10B and the second electrode layer 15 of the first vibration part 10A by using the first auxiliary electrode layer 17a, the first connection part 19a, and the connection layer 20. Therefore, the second signal line 92b can supply the driving signal, supplied from the vibration driving circuit, to the first electrode layer 13 of the second vibration part 10B and the second electrode layer 15 of the first vibration part 10A in common. Accordingly, in an embodiment of the present disclosure, two individual signal lines respectively connected to the second electrode layer 15 of the first vibration part 10A and the first electrode layer 13 of the second vibration part 10B cannot be configured, and the same signal can be applied to the second electrode layer 15 of the first vibration part 10A and the first electrode layer 13 of the second vibration part 10B by using one second signal line 92b.

According to an embodiment of the present disclosure, the third signal line 92c can be connected to the second auxiliary electrode layer 17b, between the second vibration part 10B and the second cover member 50. A signal applied to the third signal line 92c can be supplied to the first electrode layer 13 of the first vibration part 10A by using the second auxiliary electrode layer 17b, the second connection part 19b, the third auxiliary electrode layer 17c, the auxiliary connection layer 23, the fourth auxiliary electrode layer 17d, and the third connection part 19c. Therefore, the third signal line 92c can supply the driving signal, supplied from the vibration driving circuit, to the first electrode layer 13 of the first vibration part 10A in common. Accordingly, in an embodiment of the present disclosure, a separate signal line cannot be configured at a lower surface (or a lower side) of the first electrode layer 13 of the first vibration part 10A, and the signal lines 92a to 92c can be configured between the vibration generating part 10 and the second cover member 50.

In the first vibration part 10A, the first electrode layer 13 can receive the driving signal through the third signal line 92c, and the second electrode layer 15 can receive the driving signal through the second signal line 92b. Accordingly, the first vibration part 10A can alternately repeat contraction and/or expansion based on an inverse piezoelectric effect generated in the vibration layer 11 according to the driving signal, and thus, can vibrate (or displace or drive).

In the second vibration part 10B, the first electrode layer 13 can receive the driving signal through the second signal line 92b, and the second electrode layer 15 can receive the driving signal through the first signal line 92a. Accordingly, the second vibration part 10B can alternately repeat contraction and/or expansion based on an inverse piezoelectric effect generated in the vibration layer 11 according to the driving signal, and thus, can vibrate (or displace or drive).

Each of the first vibration part 10A and the second vibration part 10B can be flexed (or displaced or driven) in the same shape. Therefore, the vibration generating part 10 or the vibration apparatus can summate and maximize a vibration width (or displacement width or driving width) of the first vibration part 10A and a vibration width (or displacement width or driving width) of the second vibration part 10B. For example, the vibration generating part 10 or the vibration apparatus can reinforce a vibration of the first vibration part 10A and a vibration of the second vibration part 10B, and thus, a vibration characteristic and/or vibration efficiency can be enhanced, and a vibration width (or displacement width or driving width) can be maximized, thereby enhancing a sound characteristic and/or a sound pressure level characteristic including a sound of a low pitched sound band.

Moreover, in the vibration apparatus according to an embodiment of the present disclosure, all of the first to third signal lines 92a to 92c of the signal cable 90 can be configured between the second cover member 50 and the vibration generating part 10. Therefore, in the vibration apparatus according to an embodiment of the present disclosure, a signal line cannot be configured between a plurality of vibration parts 10A and 10B, and thus, a step height caused by a signal line and a thickness of a vibration apparatus can be reduced. Also, in the vibration apparatus according to an embodiment of the present disclosure, a crack occurring when attaching the first cover member 30 to the second cover member 50 can be prevented by a step height which occurs when connecting a signal line. For example, in the vibration apparatus according to an embodiment of the present disclosure, all of the first to third signal lines 92a to 92c can be configured at an upper surface of the vibration generating part 10, and thus, in a case where a signal line is configured between the first and second vibration generating parts 10A and 10B, a problem can be solved where a vibration layer configuring the first and second vibration generating parts 10A and 10B is broken or a defect such as a crack occurs due to the attachment of the first and second vibration generating parts 10A and 10B.

Moreover, in the vibration apparatus according to an embodiment of the present disclosure, the welded connection layer 20 and the auxiliary connection layer 23 can be configured between the first vibration part 10A and the second vibration part 10B, and thus, a thickness between the first vibration part 10A and the second vibration part 10B can be reduced, and the vibration driving device can enhance an adhesive force between the first vibration part 10A and the second vibration part 10B.

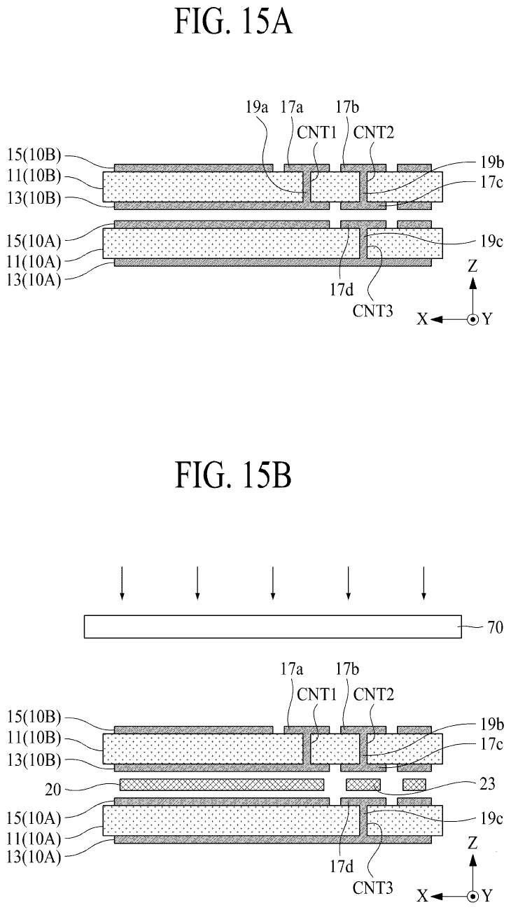

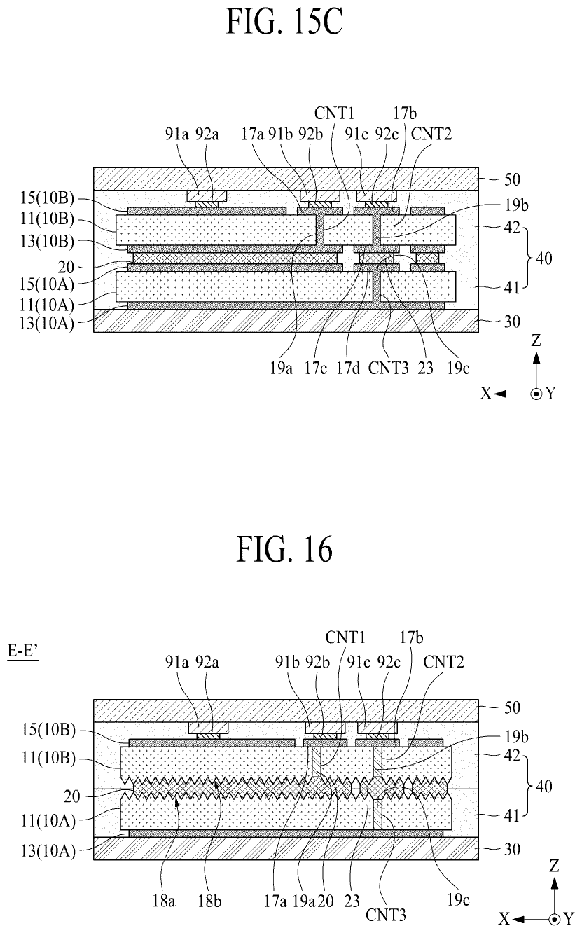

FIGS. 15A to 15C are diagrams illustrating a method of manufacturing the vibration apparatus illustrated in FIG. 9 according to an embodiment of the present disclosure. FIGS. 15A to 15C are diagrams illustrating a method of manufacturing the vibration apparatus according to an embodiment of the present disclosure described above with reference to FIGS. 9 to 14. Hereinafter, therefore, like reference numerals refer to like elements, and repeated descriptions will be briefly given or are omitted.

Referring to FIGS. 15A to 15C, a method of manufacturing a vibration apparatus according to an embodiment of the present disclosure can include a step of configuring a plurality of vibration parts 10A and 10B, a step of configuring a connection layer 20 between the plurality of vibration parts 10A and 10B, a step of configuring a signal cable 90 electrically connected to the plurality of vibration parts 10A and 10B, and a step of configuring first and second cover members 30 and 50.

Referring to FIG. 15A, the step of configuring the plurality of vibration parts (for example, first and second vibration parts) 10A and 10B can include a step of configuring a vibration layer 11. For example, the vibration layer 11 can include a piezoelectric material (or an electro active material) including a piezoelectric effect. For example, the vibration layer 11 can be configured to a width of 6 cm, a height of 12 cm, and a thickness of 165 μm, but embodiments of the present disclosure are not limited thereto.

Subsequently, a first contact hole CNT1 and a second contact hole CNT2 can be formed in the vibration layer 11 of the second vibration part 10B, and a third contact hole CNT3 can be formed in the vibration layer 11 of the first vibration part 10A. For example, the second contact hole CNT2 can be formed at one end (or one side) of each vibration layer 11 to face the third contact hole CNT3. For example, the first contact hole CNT1 and the second contact hole CNT2 can be spaced apart from each other by a certain distance.

Subsequently, a second electrode layer 14, a first auxiliary electrode layer 17a, and a second auxiliary electrode layer 17b can be formed at a second surface (or an upper surface) of the vibration layer 11 of the second vibration part 10B, and a first electrode layer 13 and a third auxiliary electrode layer 17c can be formed at a first surface (or a lower surface) of the vibration layer 11. For example, the first auxiliary electrode layer 17a and the first electrode layer 13 can be electrically connected to each other as a material used as an electrode layer and/or an auxiliary electrode layer is filled in the first contact hole CNT1, in a process of forming the first auxiliary electrode layer 17a and the first electrode layer 13. For example, the second auxiliary electrode layer 17b and the third auxiliary electrode layer 17c can be electrically connected to each other as a material used as an auxiliary electrode layer is filled in the second contact hole CNT2, in a process of forming the second auxiliary electrode layer 17b and the third auxiliary electrode layer 17c.

Subsequently, a first electrode layer 13 can be configured at a first surface (or a lower surface) of the vibration layer 11 of the first vibration part 10A, and a second electrode layer 15 and a fourth auxiliary electrode layer 17d can be configured at a second surface (or an upper surface). For example, the fourth auxiliary electrode layer 17d and the first electrode layer 13 can be electrically connected to each other as a material used as an electrode layer and/or an auxiliary electrode layer is filled in the third contact hole CNT3, in a process of forming the fourth auxiliary electrode layer 17d and the first electrode layer 13.

According to an embodiment of the present disclosure, a metal paste including silver (Ag) can be coated on a region, where an electrode layer is to be disposed, of each of the first surface and the second surface of the vibration layer 11, and then, by firing the coated metal paste, each of the first electrode layer 13, the second electrode layer 15, the first auxiliary electrode layer 17a, the second auxiliary electrode layer 17b, the third auxiliary electrode layer 17c, and the fourth auxiliary electrode layer 17d can be formed. For example, the firing can be performed for about 15 minutes at a temperate of 650° C. to 700° C., but embodiments of the present disclosure are not limited thereto. For example, the firing can include a process of performing natural cooling after being maintained for about 15 minutes at a temperate of 650° C. to 700° C., but embodiments of the present disclosure are not limited thereto. A process time can include a thermal treatment time and a natural cooling time and can be performed for about 1 hour, but embodiments of the present disclosure are not limited thereto. For example, the metal paste including silver (Ag) can be formed to have a thickness of 5 μm or less, but embodiments of the present disclosure are not limited thereto.

Referring to FIG. 15B, the step of configuring the connection layer 20 between the plurality of vibration parts 10A and 10B can be a step of forming a connection layer 20 and an auxiliary connection layer 23 at a first surface (or a lower surface) of the second vibration part 10B. First, in the connection layer 20 and the auxiliary connection layer 23, a soldering foil used as the connection layer 20 and the auxiliary connection layer 23 can be disposed at a first surface (or a lower surface) of the second electrode layer 15 of the second vibration part 10B. Subsequently, a pressure apparatus 70 can be disposed on the second vibration part 10B, a load of about 0.2 kg or more can be applied in an arrow direction, and thermal treatment can be performed on the connection layer 20 and the auxiliary connection layer 23 at a temperature of 400° C. or less. For example, a process of performing thermal treatment on the connection layer 20 and the auxiliary connection layer 23 at a temperature of 400° C. or less can be a firing step. For example, the firing step can be a step of melting a soldering foil disposed between the electrode layers 13 and 15 to weld the melted soldering foil. For example, a melting point of the soldering foil used as the connection layer 20 and the auxiliary connection layer 23 can be a range of about 100° C. to about 400° C., but embodiments of the present disclosure are not limited thereto. For example, a time for welding the soldering foil can be less than 1 hour. For example, the soldering foil can be welded for 5 minutes at about 150° C. However, embodiments of the present disclosure are not limited thereto. According to an embodiment of the present disclosure, the melted soldering foil can include a uniform surface, and as the melted soldering foil is cooled at a room temperature, the melted soldering foil can be welded to configure the connection layer 20 and the auxiliary connection layer 23. Therefore, the first vibration part 10A and the second vibration part 10B can be easily connected to each other. Accordingly, the first vibration part 10A and the second vibration part 10B can be easily bonded to each other.

Referring to FIG. 15C, the method of manufacturing a vibration apparatus according to an embodiment of the present disclosure can include a step of configuring a signal cable 90 electrically connected to a plurality of vibration parts 10A and 10B and a step of configuring first and second cover members 30 and 50.

First, the method can include a step of placing a signal line in the vibration generating part 10 and attaching a second cover member (or a protection member) 50. For example, the step of placing the signal line in the vibration generating part 10 and attaching the second cover member 50 can place a first signal line 92a on the second electrode layer 15 of the second vibration part 10B, place a second signal line 92b on the first auxiliary electrode layer 17a, place a third signal line 92c on the second auxiliary electrode layer 17b, and attach the second cover member 50 to a first surface of the vibration generating part 10 by using a lamination process using a second adhesive layer 42. Accordingly, the first signal line 92a can be electrically connected (or contact) to the second electrode layer 15 of the second vibration part 10B, the second signal line 92b can be electrically connected (or contact) to the first auxiliary electrode layer 17a, and the third signal line 92c can be electrically connected (or contact) to the second auxiliary electrode layer 17b.

Moreover, the method can further include a step of forming (or coating) a first adhesive layer 41 at a first surface of the vibration generating part 10. Accordingly, the vibration generating part 10 can be surrounded by the second cover member 50 and the first adhesive layer 41. For example, the vibration generating part 10 can be surrounded by the first adhesive layer 41 and the second adhesive layer 42, or can be buried (or accommodated) in an adhesive layer 40 including the first adhesive layer 41 and the second adhesive layer 42.

Subsequently, the method can further include a step of attaching the first cover member 30 to the first surface of the vibration generating part 10. The first cover member 30 can be connected or coupled to the first surface of the vibration generating part 10 by using a lamination process using the first adhesive layer 41. Accordingly, the vibration generating part 10 can be disposed between the first cover member 30 and the second cover member 50 and can be protected by the first cover member 30 and the second cover member 50. For example, the vibration generating part 10 can be surrounded by the first adhesive layer 41 and the second adhesive layer 42, or can be buried (or accommodated) in the adhesive layer 40 including the first adhesive layer 41 and the second adhesive layer 42.

FIG. 16 is a cross-sectional view taken along line E-E′ illustrated in FIG. 9 according to another embodiment of the present disclosure. Except for that a second electrode layer of a first vibration part is omitted, a first electrode layer of a second vibration part is omitted, and surface treatment is performed on one surface of each of vibration layers facing each other, another embodiment of the present disclosure can be substantially the same as an embodiment of the present disclosure described above with reference to FIG. 11. Hereinafter, therefore, like reference numerals refer to like elements, and repeated descriptions will be briefly given or are omitted.

Referring to FIG. 16, each of a first vibration part 10A and a second vibration part 10B according to another embodiment of the present disclosure can include a vibration layer 11 and one electrode layer 13 or 15. The first vibration part 10A according to another embodiment of the present disclosure can include a vibration layer 11 and a first electrode layer 13, and the second vibration part 10B according to another embodiment of the present disclosure can include a vibration layer 11 and a second electrode layer 15.

According to another embodiment of the present disclosure, the vibration layer 11 of the first vibration part 10A can include a first surface treatment part 18a configured at a second surface (or an upper surface) thereof facing the second vibration part 10B. The first surface treatment part 18a can be configured on the entire second surface (or upper surface) of the vibration layer 11, but embodiments of the present disclosure are not limited thereto. In the first surface treatment part 18a, a separate electrode layer cannot be configured at the second surface (or upper surface) of the vibration layer 11.

According to another embodiment of the present disclosure, the vibration layer 11 of the second vibration part 10B can include a second surface treatment part 18b configured at a first surface (or a lower surface) thereof facing the first vibration part 10A. The second surface treatment part 18b can be configured on the entire first surface (or lower surface) of the vibration layer 11, but embodiments of the present disclosure are not limited thereto. In the second surface treatment part 18b, a separate electrode layer cannot be configured at the first surface (or lower surface) of the vibration layer 11.

According to another embodiment of the present disclosure, the first surface treatment part 18a and the second surface treatment part 18b can be configured to face each other. The first surface treatment part 18a and the second surface treatment part 18b can be respectively configured at the second surface (or upper surface) of the first vibration part 10A and the first surface (or lower surface) of the second vibration part 10B facing each other. For example, the first surface treatment part 18a and the second surface treatment part 18b can be a surface-processed region (or surface) based on plasma processing, corona discharge, mechanical polishing, or chemical bonding using a silane coupling agent, but embodiments of the present disclosure are not limited thereto.

According to another embodiment of the present disclosure, in the vibration generating part 10, the first surface treatment part 18a and the second surface treatment part 18b can be respectively configured at the second surface (or upper surface) of the first vibration part 10A and the first surface (or lower surface) of the second vibration part 10B, and thus, the surface roughness of the vibration layer 111 can be enhanced. Therefore, an adhesive force of the vibration layer 11 and the connection layer 20 configured in each of the plurality of vibration parts 10A and 10B can be enhanced. Accordingly, an adhesive force of the vibration layer 11 and the auxiliary connection layer 23 configured in each of the plurality of vibration parts 10A and 10B can be enhanced.

According to another embodiment of the present disclosure, in the vibration apparatus, because an electrode layer is not configured at each of the second surface (or upper surface) of the first vibration part 10A and the first surface (or lower surface) of the second vibration part 10B and the connection layer 20 is configured, a thickness of the vibration apparatus can be more reduced.

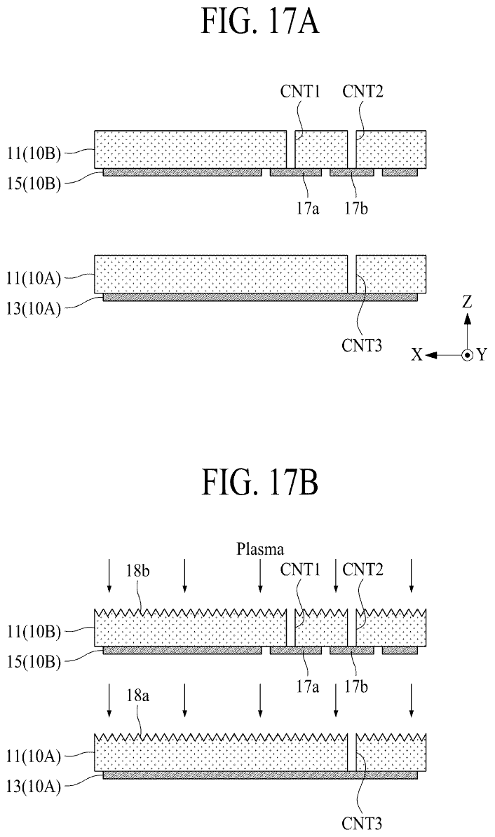

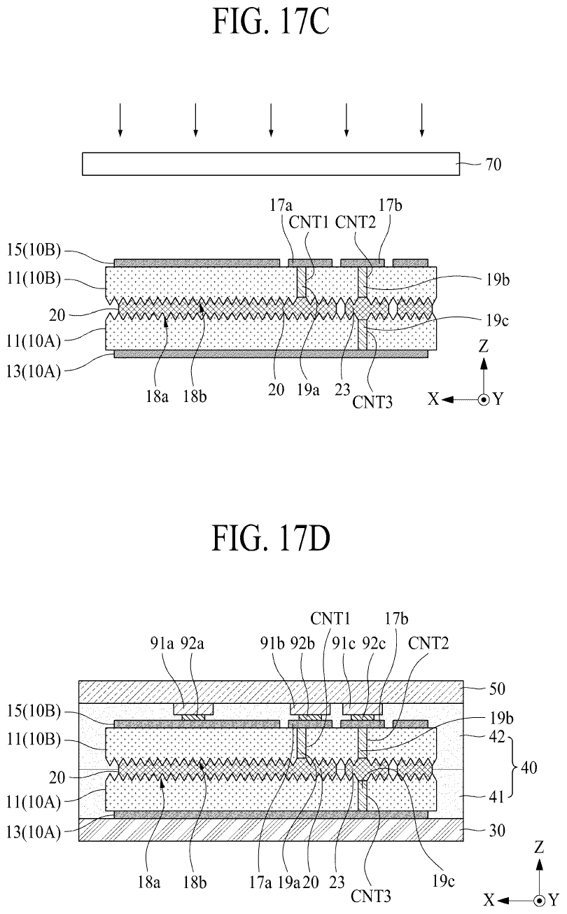

FIGS. 17A to 17D are diagrams illustrating a method of manufacturing the vibration apparatus illustrated in FIG. 16 according to another embodiment of the present disclosure. Except for the step of configuring the electrode layer and the process of configuring the surface treatment part on the vibration layers facing each other, in a step of configuring a plurality of vibration parts, the method of manufacturing the vibration apparatus according to another embodiment of the present disclosure can be substantially the same as an embodiment of the present disclosure described above with reference to FIGS. 15A to 15C. Hereinafter, therefore, like reference numerals refer to like elements, and repeated descriptions will be briefly given or are omitted.

Referring to FIGS. 17A to 17D, a method of manufacturing a vibration apparatus according to an embodiment of the present disclosure can include a step of configuring a plurality of vibration parts 10A and 10B, a step of configuring a connection layer 20 between the plurality of vibration parts 10A and 10B, a step of configuring a signal cable 90 electrically connected to the plurality of vibration parts 10A and 10B, and a step of configuring first and second cover members 30 and 50. The step of configuring the plurality of vibration parts 10A and 10B can include a step of configuring a vibration layer 11, a first electrode layer 13, and a second electrode layer 15 and a step of configuring surface treatment parts 18a and 18b.

Referring to FIG. 17A, the method of manufacturing the vibration apparatus according to an embodiment of the present disclosure can form a first electrode layer 13 at a first surface (or lower surface) of the vibration layer 11 of the first vibration part 10A and can form a second electrode layer 15, a first auxiliary electrode layer 17a, and a second auxiliary electrode layer 17b at a second surface (or upper surface) of the vibration layer 11 of the second vibration part 10B. For example, a portion of a material used as an electrode layer can be filled in a third contact hole CNT3 configured in the vibration layer 11 of the first vibration part 10A in a process of forming the first electrode layer 13, but embodiments of the present disclosure are not limited thereto. For example, a portion of a material used as an auxiliary electrode layer can be filled in each of a first contact hole CNT1 and a second contact hole CNT2 in a process of forming the first auxiliary electrode layer 17a and the second auxiliary electrode layer 17b, but embodiments of the present disclosure are not limited thereto.

Referring to FIG. 17B, the method of manufacturing the vibration apparatus can include a step of respectively configuring a first surface treatment part 18a and a second surface treatment part 18b at a second surface (or upper surface) of the vibration layer 11 of the first vibration part 10A and a first surface (or lower surface) of the vibration layer 11 of the second vibration part 10B. For example, each of the first surface treatment part 18a and the second surface treatment part 18b can be configured by plasma processing, corona discharge, mechanical polishing, or chemical bonding using a silane coupling agent, but embodiments of the present disclosure are not limited thereto. In FIG. 17B, surface treatment based on plasma is illustrated.

Referring to FIG. 17C, the step of configuring the connection layer 20 between the plurality of vibration parts 10A and 10B can be a step of forming a connection layer 20 and an auxiliary connection layer 23 between the plurality of vibration parts 10A and 10B.

First, in the connection layer 20 and the auxiliary connection layer 23, a soldering foil used as the connection layer 20 and the auxiliary connection layer 23 can be disposed between the second surface (or upper surface) of the vibration layer 11 of the first vibration part 10A and the first surface (or a lower surface) of the vibration layer 11 of the second vibration part 10B, where electrode layers 13 and 15 are not configured. Subsequently, a pressure apparatus 70 can be disposed on the second vibration part 10B, a load of about 0.2 kg or more can be applied in an arrow direction, and thermal treatment can be performed on the connection layer 20 and the auxiliary connection layer 23 at a temperature of 400° C. or less. According to an embodiment of the present disclosure, a melted soldering foil can include a uniform surface, and as the melted soldering foil is cooled at a room temperature, the melted soldering foil can be solidified to configure the connection layer 20 and the auxiliary connection layer 23. For example, the soldering foil can configure the connection layer 20 and the auxiliary connection layer 23 in a welding process. For example, in a process of forming the connection layer 20, a melted soldering foil can be inserted into the first contact hole CNT1 and welded, and thus, a first connection part 19a can be configured. Therefore, the connection layer 20 can be electrically connected to the first auxiliary electrode layer 17a. For example, in a process of forming the auxiliary connection layer 23, the melted soldering foil can be inserted into the second contact hole CNT2 and the third contact hole CNT3 and welded, and thus, a second connection part 19b and a third connection part 19c can be configured. Accordingly, the auxiliary connection layer 23 can be electrically connected to the second connection part 19b and the third connection part 19c.

Referring to FIG. 17D, in another embodiment of the present disclosure, a step of configuring a signal cable 90 and a step of configuring first and second cover members 30 and 50 can be performed identical to FIG. 15C.

According to another embodiment of the present disclosure, in the vibration generating part 10, the first surface treatment part 18a and the second surface treatment part 18b can be respectively configured at the second surface (or upper surface) of the first vibration part 10A and the first surface (or lower surface) of the second vibration part 10B facing each other, and thus, the surface roughness of the vibration layer 111 can be enhanced, thereby enhancing an adhesive force between the vibration layer 111 and the connection layer 20 and auxiliary connection layer 23.

According to another embodiment of the present disclosure, in the vibration apparatus, because an electrode layer is not configured at each of the second surface (or upper surface) of the first vibration part 10A and the first surface (or lower surface) of the second vibration part 10B facing each other and the connection layer 20 and the auxiliary connection layer are configured, a thickness of the vibration apparatus can be more reduced.

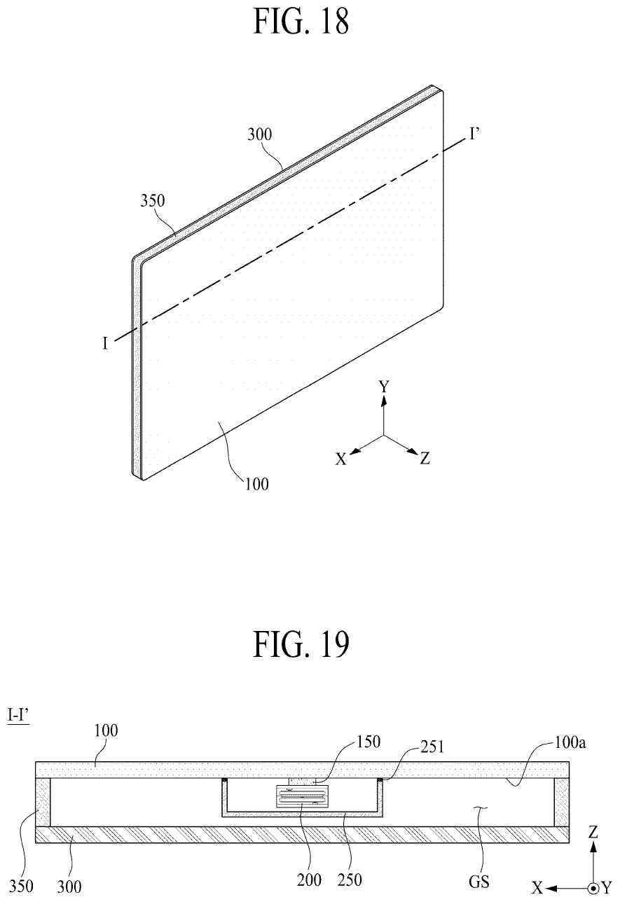

FIG. 18 is a diagram illustrating a vibration driving device according to an embodiment of the present disclosure. FIG. 19 is a cross-sectional view taken along line I-I′ illustrated in FIG. 18 according to an embodiment of the present disclosure.

Referring to FIGS. 18 and 19, a vibration driving device according to an example embodiment of the present disclosure can include a passive vibration member 100 and one or more vibration generating apparatuses 200.

The “apparatus” according to an example embodiment of the present disclosure can be a display apparatus, a sound apparatus, a sound generating apparatus, a sound bar, an analog signage, or a digital signage, or the like, but embodiments of the present disclosure are not limited thereto.

The display apparatus can include a display panel including a plurality of pixels which implement a black/white or color image and a driver configured to drive the display panel. An image according to an example embodiment of the present disclosure can include an electronic image, a digital image, a still image, or a video image, but embodiments of the present disclosure are not limited thereto. For example, the display panel can be a liquid crystal display panel, an organic light emitting display panel, a light emitting diode display panel, an electrophoresis display panel, an electro-wetting display panel, a micro light emitting diode display panel, or a quantum dot light emitting display panel, or the like, but embodiments of the present disclosure are not limited thereto. For example, in the organic light emitting display panel, a pixel can include an organic light emitting device such as an organic light emitting layer or the like, and the pixel can be a subpixel which implements any one of a plurality of colors configuring a color image. Therefore, an “apparatus” according to an example embodiment of the present disclosure can include a set device (or a set apparatus) or a set electronic device such as a notebook computer, a television (TV), a computer monitor, an equipment apparatus including an automotive apparatus or another type apparatus for vehicles, or a mobile electronic device such as a smartphone, or an electronic pad, or the like which is a complete product (or a final product) including a display panel such as an organic light emitting display panel, a liquid crystal display panel, or the like.

The analog signage can be an advertising signboard, a poster, a noticeboard, or the like. The analog signage can include content such as a sentence, a picture, and a sign, or the like. The content can be disposed at the passive vibration member 100 of the vibration driving device to be visible. For example, the content can be directly attached on the passive vibration member 100 and the content can be printed or the like on a medium such as paper, and the medium can be attached on the passive vibration member 100.

The passive vibration member 100 can vibrate based on driving (or vibration) of the one or more vibration generating apparatuses 200. For example, the passive vibration member 100 can generate one or more of a vibration and a sound based on driving of the one or more vibration generating apparatuses 200.

The passive vibration member 100 according to an example embodiment of the present disclosure can be a display panel including a display area (or a screen) having a plurality of pixels which implement a black/white or color image. Thus, the passive vibration member 100 can generate one or more of a vibration and a sound based on driving of the one or more vibration generating apparatuses 200. For example, the passive vibration member 100 can vibrate based on a vibration of the vibration generating apparatus 200 while a display area is displaying an image, and thus, can generate or output a sound synchronized with the image displayed on the display area. For example, the passive vibration member 100 according to an example embodiment of the present disclosure can be a vibration object, a display member, a display panel, a signage panel, a passive vibration plate, a front cover, a front member, a vibration panel, a sound panel, a passive vibration panel, a sound output plate, a sound vibration plate, or a video screen, but embodiments of the present disclosure are not limited thereto.

According to another example embodiment of the present disclosure, the passive vibration member 100 can be a vibration plate including a metal material or a nonmetal material (or a complex nonmetal material), which has a material characteristic suitable for outputting a sound based on a vibration of each of the one or more vibration generating apparatuses 200. For example, the passive vibration member 100 can be a vibration plate including one or more materials of metal, plastic, paper, fiber, cloth, wood, leather, rubber, glass, carbon, and mirror. For example, the paper can be a cone paper for speakers. For example, the cone paper can be pulp or foam plastic, but embodiments of the present disclosure are not limited thereto.

The passive vibration member 100 according to another example embodiment of the present disclosure can include a display panel including a pixel displaying an image, or can include a non-display panel. For example, the passive vibration member 100 can include one or more of a display panel including a pixel configured to display an image, a screen panel on which an image is to be projected from a display apparatus, a lighting panel, a light emitting diode lighting panel, an organic light emitting lighting panel, an inorganic light emitting lighting panel, a signage panel, a vehicular interior material, a vehicular exterior material, a vehicular glass window, a vehicular seat interior material, a ceiling material of a building, an interior material of a building, a glass window of a building, an interior material of an aircraft, a glass window of an aircraft, and mirror, but embodiments of the present disclosure are not limited thereto. For example, the non-display panel can be a light emitting diode lighting panel (or apparatus), an organic light emitting diode lighting panel (or apparatus), or an inorganic light emitting diode lighting panel (or apparatus), but embodiments of the present disclosure are not limited thereto.

The one or more vibration generating apparatuses 200 can be configured to vibrate the passive vibration member 100. The one or more vibration generating apparatuses 200 can be configured to be connected to a rear surface 100a of the passive vibration member 100 by a connection member 150. Accordingly, the one or more vibration generating apparatuses 200 can vibrate the passive vibration member 100, and thus, can generate or output one or more of a vibration and a sound, based on a vibration of the passive vibration member 100.

The one or more vibration generating apparatuses 200 can include one or more of the vibration apparatuses described above with reference to FIGS. 1 to 17. Accordingly, the descriptions of the vibration apparatuses provided with reference to FIGS. 1 to 17 can be applicable to the vibration apparatuses illustrated with reference to FIGS. 18 and 19, and thus, like reference numerals can refer to like elements and repetitive descriptions thereof can be omitted.

The connection member 150 can be disposed between at least a portion of the vibration generating apparatus 200 and the passive vibration member 100. The connection member 150 can be connected between at least a portion of the vibration generating apparatus 200 and the passive vibration member 100. The connection member 150 according to an example embodiment of the present disclosure can be connected between a center portion, except a periphery portion (or an edge portion), of the vibration generating apparatus 200 and the passive vibration member 100. For example, the connection member 150 can be connected between the center portion of the vibration generating apparatus 200 and the passive vibration member 100, based on a partial attachment scheme. The center portion (or a middle portion) of the vibration generating apparatus 200 can be a center of a vibration, and thus, a vibration of the vibration generating apparatus 200 can be efficiently transferred to the passive vibration member 100 through the connection member 150. The periphery portion (or the edge portion) of the vibration generating apparatus 200 can be in a state where the periphery portion (or the edge portion) of the vibration generating apparatus 200 is raised from each of the connection member 150 and the passive vibration member 100 without being connected to the connection member 150 and/or the passive vibration member 100, and thus, when a flexural vibration (or a bending vibration) of the vibration generating apparatus 200 is performed, a vibration of the edge portion of the vibration generating apparatus 200 cannot be reduced (prevented) by the connection member 150 and/or the passive vibration member 100, and thus, a vibration width (or a displacement width or a driving width) of the vibration generating apparatus 200 can increase. Accordingly, a vibration width (or a displacement width or a driving width) of the passive vibration member 100 based on a vibration of the vibration generating apparatus 200 can increase, and thus, a sound characteristic and a sound pressure level characteristic of a low-pitched sound band generated based on a vibration of the passive vibration member 100 can be further enhanced.

According to another example embodiment of the present disclosure, the connection member 150 can be connected to or attached on or at an entire front surface of the one or more vibration generating apparatuses 200 and the rear surface 100a of the passive vibration member 100, based on a front attachment scheme.

The connection member 150 according to an example embodiment of the present disclosure can include a material including an adhesive layer which is good in adhesive force or attaching force with respect to the rear surface of the passive vibration member 100 or the display panel and each of the one or more vibration generating apparatuses 200. For example, the connection member 150 can include a foam pad, a double-sided tape, an adhesive, or the like, but embodiments of the present disclosure are not limited thereto. For example, an adhesive layer of the connection member 150 can include epoxy, acryl, silicone, or urethane, but embodiments of the present disclosure are not limited thereto. For example, the adhesive layer of the connection member 150 can include an acryl-based material, having a characteristic where an adhesive force is relatively good and hardness is high, comparted to a urethane-based material. Accordingly, a vibration of each of the one or more vibration generating apparatuses 200 can be well transferred to the passive vibration member 100.

The vibration driving device according to an example embodiment of the present disclosure can further include a supporting member 300 and a coupling member 350.

The supporting member 300 can be disposed at the rear surface 100a of the passive vibration member 100. The supporting member 300 can be disposed at the rear surface 100a of the passive vibration member 100 to cover the vibration generating apparatus 200. The supporting member 300 can be disposed at the rear surface 100a of the passive vibration member 100 to cover an entire of the rear surface 100a of the passive vibration member 100 and the vibration generating apparatus 200. For example, the supporting member 300 can have a size which is equal to that of the passive vibration member 100. For example, the supporting member 300 can cover the rear surface 100a of the passive vibration member 100 with the vibration generating apparatus 200 and a gap space GS therebetween. For example, the supporting member 300 can cover the entire rear surface 100a of the passive vibration member 100 with the vibration generating apparatus 200 and the gap space GS therebetween. The gap space GS can be provided by the coupling member 350 disposed between the passive vibration member 100 and the supporting member 300 facing each other. The gap space GS can be referred to as an air gap, an accommodating space, a vibration space, and a sounding box, but embodiments of the present disclosure are not limited thereto.

The supporting member 300 can include one or more materials of a glass material, a metal material, and a plastic material. The supporting member 300 can have a stack structure where one or more materials of a glass material, a metal material, and a plastic material are stacked.

Each of the passive vibration member 100 and the supporting member 300 can have a square shape or a rectangular shape, but embodiments of the present disclosure are not limited thereto. For example, each of the passive vibration member 100 and the supporting member 300 can have a polygonal shape, a non-polygonal shape, a circular shape, or an oval shape. For example, in a case where the vibration driving device according to an example embodiment of the present disclosure is applied to a sound apparatus or a sound bar, each of the passive vibration member 100 and the supporting member 300 can have a rectangular shape where a long-side length is twice or longer than a short-side length, but embodiments of the present disclosure are not limited thereto.

The coupling member 350 can be configured to be connected between a rear edge portion (or a rear periphery portion) of the passive vibration member 100 and a front edge portion (or a front periphery portion) of the supporting member 300, and thus, the gap space GS can be provided between the passive vibration member 100 and the supporting member 300 facing each other.

The coupling member 350 according to an example embodiment of the present disclosure can include an clastic material which has adhesive properties and is capable of compression and decompression. For example, the coupling member 350 can include a double-side tape, a single-sided tape, or a double-side adhesive foam pad, but embodiments of the present disclosure are not limited thereto. For example, the coupling member 350 can include an elastic pad such as a rubber pad or a silicone pad, which has adhesive properties and is capable of compression and decompression. For example, the coupling member 350 can be formed by an elastomer.

As another example, the supporting member 300 can further include a sidewall portion which supports the rear edge portion (or the rear periphery portion) of the passive vibration member 100. The sidewall portion of the supporting member 300 can protrude or be bent toward the rear edge portion (or the rear periphery portion) of the passive vibration member 100 from the front edge portion (or the front periphery portion) of the supporting member 300, and thus, the gap space GS can be provided between the passive vibration member 100 and the supporting member 300. In this case, the coupling member 350 can be configured to be connected between the sidewall portion of the supporting member 300 and the rear edge portion (or the rear periphery portion) of the passive vibration member 100. Accordingly, the supporting member 300 can cover the one or more vibration generating apparatuses 200 and can support the rear surface 100a of the passive vibration member 100. For example, the supporting member 300 can cover the one or more vibration generating apparatuses 200 and can support the rear edge portion (or the rear periphery portion) of the passive vibration member 100.

As another example, the passive vibration member 100 can further include a sidewall portion which is connected to the front edge portion (or the front periphery portion) of the supporting member 300. The sidewall portion of the passive vibration member 100 can protrude or be bent toward the front edge portion (or the front periphery portion) of the supporting member 300 from the rear edge portion (or the rear periphery portion) of the passive vibration member 100, and thus, the gap space GS can be provided between the passive vibration member 100 and the supporting member 300. The passive vibration member 100 can increase in stiffness by the sidewall portion thereof. In this case, the coupling member 350 can be configured to be connected between the sidewall portion of the passive vibration member 100 and the rear edge portion (or the rear periphery portion) of the supporting member 300. Accordingly, the supporting member 300 can cover the one or more vibration generating apparatuses 200 and can support the rear surface 100a of the passive vibration member 100. For example, the supporting member 300 can cover the one or more vibration generating apparatuses 200 and can support the rear edge portion (or the rear periphery portion) of the passive vibration member 100.

The vibration driving device according to an example embodiment of the present disclosure can further include one or more enclosures 250.

The enclosure 250 can be connected or coupled to the rear edge portion (or the rear periphery portion) of the passive vibration member 100 to individually cover the one or more vibration generating apparatuses 200. For example, the enclosure 250 can be connected or coupled to the rear surface 100a of the passive vibration member 100 by a coupling member 251. The enclosure 250 can configure a sealing space, which covers or surrounds the one or more vibration generating apparatuses 200, at the rear surface 100a of the passive vibration member 100. For example, the enclosure 250 can be a sealing member, a sealing cap, a sealing box, or a sound box, but embodiments of the present disclosure are not limited thereto. The sealing space can be an air gap, a vibration space, a sound space, or a sounding box, but embodiments of the present disclosure are not limited thereto.

The enclosure 250 can include one or more materials of a metal material and a nonmetal material (or a complex nonmetal material). For example, the enclosure 250 can include one or more materials of metal, plastic, and wood, but embodiments of the present disclosure are not limited thereto.

The enclosure 250 according to an example embodiment of the present disclosure can maintain a constant impedance component based on air acting on the passive vibration member 100 when the passive vibration member 100 or the vibration generating apparatus 200 vibrates. For example, air around the passive vibration member 100 can resist to a vibration of the passive vibration member 100 and can act as an impedance component having a resistance and a reactance component, which vary based on a frequency. Accordingly, the enclosure 250 can configure (or form) a sealing space, which surrounds the one or more vibration generating apparatuses 200, at the rear surface 100a of the passive vibration member 100, and thus, can maintain a constant impedance component (or an air impedance or an elastic impedance) acting on the passive vibration member 100 with air, thereby enhancing a sound characteristic and/or a sound pressure level characteristic of a low-pitched sound band and the sound quality of a high-pitched sound band.

A vibration apparatus and an vibration driving device including the vibration apparatus according to example embodiments of the present disclosure are described below.

A vibration apparatus according to one or more embodiments of the present disclosure can comprise a vibration generating part including a plurality of vibration parts, and a connection layer welded between the plurality of vibration parts. The connection layer comprises a conductive material.

According to one or more embodiments of the present disclosure, the connection layer can comprise a soldering foil welded by one or more of heat and an ultrasound.

According to one or more embodiments of the present disclosure, the plurality of vibration parts can comprise a first vibration part and a second vibration part, which are vertically stacked, and the connection layer can be between the first vibration part and the second vibration part.

According to one or more embodiments of the present disclosure, each of the first vibration part and the second vibration part can comprise a first electrode layer, a second electrode layer, and a vibration layer can be between the first electrode layer and the second electrode layer, the vibration layer including a piezoelectric material. The connection layer can be between the second electrode layer of the first vibration part and the first electrode layer of the second vibration part.

According to one or more embodiments of the present disclosure, the vibration layer of the first vibration part and the vibration layer of the second vibration part can have different poling directions.

According to one or more embodiments of the present disclosure, the vibration apparatus can further comprise a first cover member connected to a first surface of the vibration generating part, a second cover member connected to a second surface of the vibration generating part, a first adhesive layer between the vibration generating part and the first cover member, and a second adhesive layer between the vibration generating part and the second cover member.

According to one or more embodiments of the present disclosure, the vibration apparatus can further comprise a signal cable accommodated between the first cover member and the second cover member and including first to third signal lines electrically connected to the vibration generating part. The first signal line can be connected to the second electrode layer of the second vibration part, between the second vibration part and the second cover member, the second signal line can be connected to the connection layer, between the first vibration part and the second vibration part, and the third signal line can be connected to the first electrode layer of the first vibration part, between the first vibration part and the first cover member.

According to one or more embodiments of the present disclosure, the second vibration part can further comprise a first auxiliary electrode layer and a second auxiliary electrode layer disposed at a second surface of the vibration layer to be electrically disconnected from each other and electrically disconnected from the second electrode layer. The first auxiliary electrode layer can be electrically connected to the connection layer, and the second auxiliary electrode layer can be electrically connected to the first electrode layer of the first vibration part.

According to one or more embodiments of the present disclosure, the vibration apparatus can further comprise a signal cable accommodated between the first cover member and the second cover member and including first to third signal lines electrically connected to the vibration generating part. The first signal line can be connected to the second electrode layer of the second vibration part, between the second vibration part and the second cover member, the second signal line can be connected to the first auxiliary electrode layer, between the second vibration part and the second cover member, and the third signal line can be connected to the second auxiliary electrode layer, between the second vibration part and the second cover member.

According to one or more embodiments of the present disclosure, the vibration apparatus can further comprise a first connection part configured in the vibration layer of the second vibration part, a second connection part configured in the vibration layer of the second vibration part and spaced apart from the first connection part, and a third connection part configured in the vibration layer of the first vibration part. The first connection part can connect the first auxiliary electrode layer to the connection layer, and the second connection part and the third connection part can connect the second auxiliary electrode layer to the first electrode layer of the first vibration part.

According to one or more embodiments of the present disclosure, each of the first vibration part and the second vibration part can comprise an electrode layer, and a vibration layer between the first vibration part and the second vibration part, the vibration layer including a piezoelectric material. The connection layer can be between the vibration layer of the first vibration part and the vibration layer of the second vibration part.

According to one or more embodiments of the present disclosure, each of surfaces, facing each other, of the vibration layer of the first vibration part and the vibration layer of the second vibration part can be surface-processed by one of plasma processing, corona discharge, mechanical polishing, or chemical bonding using a silane coupling agent.

According to one or more embodiments of the present disclosure, the vibration apparatus can further comprise a first cover member connected to a first surface of the vibration generating part, a second cover member connected to a second surface of the vibration generating part, a first adhesive layer between the vibration generating part and the first cover member, and a second adhesive layer between the vibration generating part and the second cover member.

According to one or more embodiments of the present disclosure, the second vibration part can further comprise a first auxiliary electrode layer and a second auxiliary electrode layer disposed at a second surface of the vibration layer to be electrically disconnected from each other and electrically disconnected from the electrode layer of the second vibration part. The first auxiliary electrode layer can be electrically connected to the connection layer, and the second auxiliary electrode layer can be electrically connected to the electrode layer of a first surface of the first vibration part.

According to one or more embodiments of the present disclosure, the vibration apparatus can further comprise a signal cable accommodated between the first cover member and the second cover member and including first to third signal lines electrically connected to the vibration generating part. The first signal line can be connected to the electrode layer of the second vibration part, between the second vibration part and the second cover member, the second signal line can be connected to the first auxiliary electrode layer, between the second vibration part and the second cover member, and the third signal line can be connected to the second auxiliary electrode layer, between the second vibration part and the second cover member.

According to one or more embodiments of the present disclosure, the vibration apparatus can further comprise a first connection part configured in the vibration layer of the second vibration part, a second connection part configured in the vibration layer of the second vibration part and spaced apart from the first connection part, and a third connection part configured in the vibration layer of the first vibration part. The first connection part can connect the first auxiliary electrode layer to the connection layer, and the second connection part and the third connection part can connect the second auxiliary electrode layer to the electrode layer of the first vibration part.

A method of manufacturing a vibration apparatus according to one or more embodiments of the present disclosure can comprise a step of configuring a vibration generating part including a plurality of vibration parts, a step of configuring a connection layer welded between the plurality of vibration parts, a step of configuring a signal cable electrically connected to the plurality of vibration parts, a step of respectively configuring first and second cover members at a first surface and a second surface of the vibration generating part. The connection layer can comprise a conductive material.

According to one or more embodiments of the present disclosure, the connection layer can comprise a soldering foil welded by one or more of heat and an ultrasound.

According to one or more embodiments of the present disclosure, the plurality of vibration parts can comprise a first vibration part and a second vibration part, which are vertically stacked, and the connection layer can be between the first vibration part and the second vibration part.

According to one or more embodiments of the present disclosure, each of the first vibration part and the second vibration part can comprise a first electrode layer, a second electrode layer, and a vibration layer between the first electrode layer and the second electrode layer, the vibration layer including a piezoelectric material. The connection layer can be between the second electrode layer of the first vibration part and the first electrode layer of the second vibration part.

According to one or more embodiments of the present disclosure, the step of configuring the connection layer and the step of configuring the signal cable can be simultaneously performed at a temperature of 400° C. or less by using a pressure stack process.

According to one or more embodiments of the present disclosure, the step of configuring the connection layer, the step of configuring the signal cable, and the step of configuring the first and second cover members can be simultaneously performed at a temperature of 200° C. or less by using a low temperature bonding process.

According to one or more embodiments of the present disclosure, the method can further comprise after the low temperature bonding process, a step of poling the plurality of vibration parts, and a step of applying an ultrasound signal to the plurality of vibration parts. The connection layer can welded by heat and/or an ultrasound which are/is generated as the ultrasound signal is applied to the plurality of vibration parts.

According to one or more embodiments of the present disclosure, the signal cable can comprise first to third signal lines accommodated between the first cover member and the second cover member. The first signal line can be connected to the second electrode layer of the second vibration part, between the second vibration part and the second cover member, the second signal line can be connected to the connection layer, between the first vibration part and the second vibration part, and the third signal line can be connected to the first electrode layer of the first vibration part, between the first vibration part and the first cover member.

According to one or more embodiments of the present disclosure, the method can further comprise a step of forming a first auxiliary electrode layer and a second auxiliary electrode layer of the second vibration part disposed at a second surface of the vibration layer to be electrically disconnected from each other and electrically disconnected from the second electrode layer. The first auxiliary electrode layer can be electrically connected to the connection layer, and the second auxiliary electrode layer can be electrically connected to the first electrode layer of the first vibration part.

According to one or more embodiments of the present disclosure, the step of configuring the connection layer can be performed at a temperature of 400° C. or less by using a pressure stack process.

According to one or more embodiments of the present disclosure, the signal cable comprises first to third signal lines can accommodate between the second surface of the vibration generating part and the second cover member. The first signal line can be connected to the second electrode layer of the second vibration part, between the second vibration part and the second cover member, the second signal line can be connected to the first auxiliary electrode layer, between the second vibration part and the second cover member, and the third signal line can be connected to the second auxiliary electrode layer, between the second vibration part and the second cover member.

According to one or more embodiments of the present disclosure, each of the first vibration part and the second vibration part can comprise an electrode layer, and a vibration layer between the first vibration part and the second vibration part, the vibration layer including a piezoelectric material. The connection layer can be between the vibration layer of the first vibration part and the vibration layer of the second vibration part.

According to one or more embodiments of the present disclosure, before the step of configuring the connection layer between the plurality of vibration parts, the method can further comprise a step of surface-processing each of surfaces, facing each other, of the vibration layer of the first vibration part and the vibration layer of the second vibration part, by one of plasma processing, corona discharge, mechanical polishing, or chemical bonding using a silane coupling agent.

According to one or more embodiments of the present disclosure, the method can further comprise a step of forming a first auxiliary electrode layer and a second auxiliary electrode layer of the second vibration part disposed at a second surface of the vibration layer to be electrically disconnected from each other and electrically disconnected from the electrode layer of the second vibration part. The first auxiliary electrode layer can be electrically connected to the connection layer, and the second auxiliary electrode layer can be electrically connected to the first electrode layer of a first surface of the first vibration part.

According to one or more embodiments of the present disclosure, the step of configuring the connection layer can be performed at a temperature of 400° C. or less by using a pressure stack process.

According to one or more embodiments of the present disclosure, the signal cable can comprise first to third signal lines accommodated between a second surface of the vibration generating part and the second cover member. The first signal line can be connected to the electrode layer of the second vibration part, between the second vibration part and the second cover member, the second signal line can be connected to the first auxiliary electrode layer, between the second vibration part and the second cover member, and the third signal line can be connected to the second auxiliary electrode layer, between the second vibration part and the second cover member.

A vibration driving device according to one or more embodiments of the present disclosure can comprise a passive vibration member, a vibration generating apparatus connected to the passive vibration member to vibrate the passive vibration member. The vibration generating apparatus comprises the vibration apparatus. The vibration apparatus can comprise a vibration generating part including a plurality of vibration parts, and a connection layer welded between the plurality of vibration parts. The connection layer comprises a conductive material.

According to one or more embodiments of the present disclosure, the vibration driving device further comprise an enclosure disposed at a rear surface of the passive vibration member.

According to one or more embodiments of the present disclosure, the passive vibration member can comprise one or more of a vibration plate, a display panel including a pixel displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a vehicular means, a ceiling material of a building, an interior material of a building, a glass window of a building, an interior material of an aircraft, a glass window of an aircraft, and a mirror. The vibration plate can comprise one or more materials of metal, plastic, paper, fiber, cloth, leather, wood, rubber, glass, and carbon.

A vibration apparatus according to one or more example embodiments of the present disclosure can be applied to or included in a vibration generating apparatus and/or a sound generating apparatus provided in a vibration driving device. The vibration apparatus and apparatus comprising the same according to one or more example embodiments of the present disclosure can be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like. In addition, the vibration apparatus according to some example embodiments of the present disclosure can be applied to or included in organic light-emitting lighting apparatuses or inorganic light-emitting lighting apparatuses. When the vibration apparatus of one or more example embodiments of the present disclosure is applied to or included in lighting apparatuses, the vibration apparatus can act as a lighting device and a speaker. In addition, when the vibration apparatus according to some example embodiments of the present disclosure is applied to or included in a mobile device, or the like, the vibration apparatus can be one or more of a speaker, a receiver, and a haptic device, but embodiments of the present disclosure are not limited thereto.

It will be apparent to those skilled in the art that various modifications and variations can be made in the present disclosure without departing from the scope of the disclosures. Thus, it is intended that the present disclosure covers the modifications and variations of this disclosure. The appended claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A vibration apparatus comprising:
a vibration assembly including a plurality of piezoelectric layers; and
a connection layer coupled between the plurality of piezoelectric layers, wherein the connection layer comprises a conductive material.

2. The vibration apparatus of claim 1, wherein the connection layer comprises a soldering foil welded between the plurality of piezoelectric layers.

3. The vibration apparatus of claim 1, wherein the plurality of piezoelectric layers comprise a first piezoelectric layer and a second piezoelectric layer, which are vertically stacked, and
wherein the connection layer is between the first piezoelectric layer and the second piezoelectric layer.

4. The vibration apparatus of claim 3, wherein each of the first piezoelectric layer and the second piezoelectric layer comprises:
a first electrode layer;
a second electrode layer; and
a vibration layer between the first electrode layer and the second electrode layer, the vibration layer including a piezoelectric material, and
wherein the connection layer is between the second electrode layer of the first piezoelectric layer and the first electrode layer of the second piezoelectric layer.

5. The vibration apparatus of claim 4, further comprising:
a first cover member connected to a first surface of the vibration assembly;
a second cover member connected to a second surface of the vibration assembly;
a first adhesive layer between the vibration assembly and the first cover member; and
a second adhesive layer between the vibration assembly and the second cover member.

6. The vibration apparatus of claim 5, further comprising:
a signal cable accommodated between the first cover member and the second cover member and including first, second, and third signal lines electrically connected to the vibration assembly,
wherein the first signal line is connected to the second electrode layer of the second piezoelectric layer between the second piezoelectric layer and the second cover member,
wherein the second signal line is connected to the connection layer between the first piezoelectric layer and the second piezoelectric layer, and
wherein the third signal line is connected to the first electrode layer of the first piezoelectric layer between the first piezoelectric layer and the first cover member.

7. The vibration apparatus of claim 5, wherein the second piezoelectric layer further comprises a first auxiliary electrode layer and a second auxiliary electrode layer disposed at a second surface of the vibration layer of the second piezoelectric layer and electrically isolated from each other, the first auxiliary electrode layer and the second auxiliary electrode layer electrically isolated from the second electrode layer,
wherein the first auxiliary electrode layer is electrically connected to the connection layer, and
wherein the second auxiliary electrode layer is electrically connected to the first electrode layer of the first piezoelectric layer.

8. The vibration apparatus of claim 7, further comprising:
a signal cable accommodated between the first cover member and the second cover member and including first, second, and third signal lines electrically connected to the vibration assembly,
wherein the first signal line is connected to the second electrode layer of the second piezoelectric layer between the second piezoelectric layer and the second cover member,
wherein the second signal line is connected to the first auxiliary electrode layer between the second piezoelectric layer and the second cover member, and
wherein the third signal line is connected to the second auxiliary electrode layer between the second piezoelectric layer and the second cover member.

9. The vibration apparatus of claim 3, wherein each of the first piezoelectric layer and the second piezoelectric layer comprises:
an electrode layer; and
a vibration layer between the first piezoelectric layer and the second piezoelectric layer, the vibration layer including a piezoelectric material, and
wherein the connection layer is between the vibration layer of the first piezoelectric layer and the vibration layer of the second piezoelectric layer.

10. The vibration apparatus of claim 9, further comprising:
a first cover member connected to a first surface of the vibration assembly;
a second cover member connected to a second surface of the vibration assembly;
a first adhesive layer between the vibration assembly and the first cover member; and
a second adhesive layer between the vibration assembly and the second cover member.

11. The vibration apparatus of claim 10, wherein the second piezoelectric layer further comprises a first auxiliary electrode layer and a second auxiliary electrode layer disposed at a second surface of the vibration layer of the second piezoelectric layer and electrically isolated from each other, the first auxiliary electrode layer and the second auxiliary electrode layer electrically isolated from the electrode layer of the second piezoelectric layer,
wherein the first auxiliary electrode layer is electrically connected to the connection layer, and
wherein the second auxiliary electrode layer is electrically connected to the electrode layer of a first surface of the first piezoelectric layer.

12. The vibration apparatus of claim 11, further comprising:
a signal cable accommodated between the first cover member and the second cover member and including first, second, and third signal lines electrically connected to the vibration assembly,
wherein the first signal line is connected to the electrode layer of the second piezoelectric layer between the second piezoelectric layer and the second cover member,
wherein the second signal line is connected to the first auxiliary electrode layer between the second piezoelectric layer and the second cover member, and
wherein the third signal line is connected to the second auxiliary electrode layer between the second piezoelectric layer and the second cover member.

13. A method of manufacturing a vibration apparatus, the method comprising:
arranging a plurality of piezoelectric layers in a vibration assembly;
welding a connection layer between the plurality of piezoelectric layers;
electrically connecting a signal cable to the plurality of vibration parts; and
coupling first and second cover members at a first surface and a second surface of the vibration assembly,
wherein the connection layer comprises a conductive material.

14. The method of manufacturing a vibration apparatus of claim 13, wherein the welding the connection layer comprises soldering foil by one or more of heat and an ultrasound.

15. The method of manufacturing a vibration apparatus of claim 13, wherein the plurality of piezoelectric layers comprise a first piezoelectric layer and a second piezoelectric layer, which are vertically stacked, and the connection layer is between the first piezoelectric layer and the second piezoelectric layer.

16. The method of manufacturing a vibration apparatus of claim 15, wherein each of the first piezoelectric layer and the second piezoelectric layer comprises:
a first electrode layer;
a second electrode layer; and
a vibration layer between the first electrode layer and the second electrode layer, the vibration layer including a piezoelectric material, and
wherein the connection layer is between the second electrode layer of the first piezoelectric layer and the first electrode layer of the second piezoelectric layer.

17. The method of manufacturing a vibration apparatus of claim 13, wherein the welding the connection layer and the electrically connecting the signal cable are simultaneously performed at a temperature of 400° C. or less by using a pressure stack process.

18. The method of manufacturing a vibration apparatus of claim 16, wherein the welding the connection layer, the electrically connecting the signal cable, and the coupling the first and second cover members are simultaneously performed at a temperature of 200° C. or less by using a low temperature bonding process.

19. A vibration driving device comprising:
a passive vibration member;
a vibration assembly connected to the passive vibration member and configured to vibrate the passive vibration member,
wherein the vibration assembly includes:
a plurality of piezoelectric layers; and
a connection layer coupled between the plurality of piezoelectric layers,
wherein the connection layer comprises a conductive material.

20. The vibration driving device of claim 19, wherein the passive vibration member comprises one or more of: a vibration plate, a display panel including a pixel displaying an image, a screen panel on which an image is configured to be projected from a display apparatus, a light emitting diode lighting panel, an organic light emitting lighting panel, an inorganic light emitting lighting panel, a signage panel, an interior material of a vehicle, an exterior material of a vehicle, a glass window of a vehicle, a seat interior material of a vehicle, a ceiling material of a vehicle, a ceiling material of a building, an interior material of a building, a glass window of a building, an interior material of an aircraft, a glass window of an aircraft, and a mirror, and
wherein the vibration assembly comprises one or more materials selected from: metal, plastic, paper, fiber, cloth, leather, wood, rubber, glass, and carbon.
